(19) United States
(12) Patent Application Publication
(10) Pub. No.: US 2025/0386520 A1
(43) Pub. Date: Dec. 18, 2025

(54) SEMICONDUCTOR DEVICE AND MANUFACTURING METHOD OF THE SAME

(71) Applicant: Samsung Electronics Co., Ltd., Suwon-si (KR)

(72) Inventors: Jeon Il Lee, Suwon-si (KR); Seryeun Yang, Suwon-si (KR); Seoha Lee, Suwon-si (KR)

(21) Appl. No.: 18/989,028

(22) Filed: Dec. 20, 2024

(30) Foreign Application Priority Data
Jun. 18, 2024 (KR) 10-2024-0079201

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2225/06541; H01L 2924/1431; H01L 2924/1436

(57) ABSTRACT

The present disclosure relates to a semiconductor device and a manufacturing method therefor. A semiconductor device includes a cell structure including a first substrate and a plurality of memory cells on the first substrate; a first logic structure on the cell structure and including a second substrate and a first logic circuit on the second substrate; a second logic structure on the first logic structure and including a third substrate and a second logic circuit on the third substrate; and a through via extending through a first insulating pattern in the second substrate and a second insulating pattern in the third substrate.

### CROSS-REFERENCE TO RELATED APPLICATION

This application claims priority to and the benefit of Korean Patent Application No. 10-2024-0079201, filed in the Korean Intellectual Property Office on Jun. 18, 2024, the entire contents of which are incorporated herein by reference.

### FIELD

The present disclosure relates to a semiconductor device and a manufacturing method therefor.

### BACKGROUND

In the von Neumann structure, a memory device and an arithmetic device may be provided separately, and the arithmetic device may operate by receiving data from the memory device and performing calculations. In this structure, when larger amounts of computation are required, such as in artificial neural network computation, the computation speed may be reduced due to the time that may be required to transfer data between the memory device and the arithmetic device. Accordingly, a memory device with a processing in memory (PIM) structure that can process at least some computations within the memory device has been proposed.

A memory device with the PIM structure may be physically larger than a conventional memory device, due to inclusion of a computation circuit and a cache memory used in the computation circuit.

### SUMMARY

Embodiments attempts to provide a semiconductor device of reduced size and a manufacturing method for a semiconductor device with a simplified manufacturing process.

An embodiment of the present disclosure provides a semiconductor device including a cell structure including a first substrate and a plurality of memory cells on the first substrate; a first logic structure on the cell structure opposite the first substrate and including a second substrate and a first logic circuit on the second substrate; a second logic structure on the first logic structure opposite the cell structure and including a third substrate and a second logic circuit on the third substrate; and a through via extending through a first insulating pattern in the second substrate and a second insulating pattern in the third substrate.

An embodiment of the present disclosure provides a semiconductor device including a cell structure including a first substrate, a plurality of memory cells on the first substrate, and a first wiring layer electrically connected to the memory cells; a first logic structure including a second substrate, a first logic circuit on the second substrate, and a second wiring layer electrically connected to the first logic circuit and the first wiring layer; a second logic structure including a third substrate, a second logic circuit on the third substrate, and a third wiring layer electrically connected to the second logic circuit and the second wiring layer; and a through via extending through the second substrate and the third substrate and electrically connecting the second wiring layer and the third wiring layer, wherein the through via is extends through a first insulating pattern in the second substrate and a second insulating pattern in the third substrate, and the through via is tapered from a first surface that is in contact with the second wiring layer to a second surface that is in contact with the third wiring layer, or is tapered from the second surface to the first surface.

An embodiment of the present disclosure provides a manufacturing method for a semiconductor device including forming a first logic circuit on a front surface of a first substrate, and a second logic circuit on a front surface of a second substrate; reducing a thickness of the first substrate by performing a first wafer thinning process on a back surface that is opposite the front surface of the first substrate to expose a first insulating pattern in the first substrate; reducing a thickness of the second substrate by performing a second wafer thinning process on a back surface that is opposite the front surface of the second substrate to expose a second insulating pattern in the second substrate; forming a first oxide layer on the back surface of the first substrate and a second oxide layer on the back surface of the second substrate, and bonding the first oxide layer and the second oxide layer such that the first insulating pattern and the second insulating pattern overlap in a direction perpendicular to the back surface of the first substrate and the back surface of the second substrate; forming a through via extending through the first insulating pattern and the second insulating pattern, with the first oxide layer and the second oxide layer between the first insulating pattern and the second insulating pattern, where a width of the through via is tapered from the front surface of the second substrate to the front surface of the first substrate, or from the front surface of the first substrate to the front surface of the second substrate.

According to the embodiments, a size of the semiconductor device may be reduced and the manufacturing process for the semiconductor device may be simplified.

### BRIEF DESCRIPTION OF THE DRAWINGS

FIG. 1 illustrates a cross-sectional view of a semiconductor device according to an embodiment.

FIG. 2 illustrates an enlarged view of a region R1 in FIG. 1.

FIG. 3 illustrates an enlarged view of the region R1 in FIG. 1 to describe a modified example of a semiconductor device according to an embodiment.

FIG. 4 illustrates an enlarged view of the region R1 in FIG. 1 to describe a modified example of a semiconductor device according to an embodiment.

FIG. 5 illustrates a cross-sectional view of a semiconductor device according to an embodiment.

FIG. 6 illustrates an enlarged view of a region R2 in FIG. 5.

FIG. 7 illustrates an enlarged view of the region R2 in FIG. 5 to describe a modified example of a semiconductor device according to an embodiment.

FIG. 8 illustrates an enlarged view of the region R2 in FIG. 5 to describe a modified example of a semiconductor device according to an embodiment.

FIGS. 9, 10, 11, 12, 13, 14, 15, and 16 illustrate cross-sectional views showing a manufacturing method for a semiconductor device according to embodiments.

FIGS. 17, 18, 19, 20, 21, 22, and 23 illustrate cross-sectional views showing a manufacturing method for a semiconductor device according to embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. The term “and/or” includes any and all combinations of one or more of the associated listed items. The term “connected” may be used herein to refer to a physical and/or electrical connection.

Further, throughout the specification, the phrase “in a plan view” means when an object portion is viewed from above, and the phrase “in a cross-sectional view” means when a cross-section taken by vertically cutting an object portion is viewed from the side.

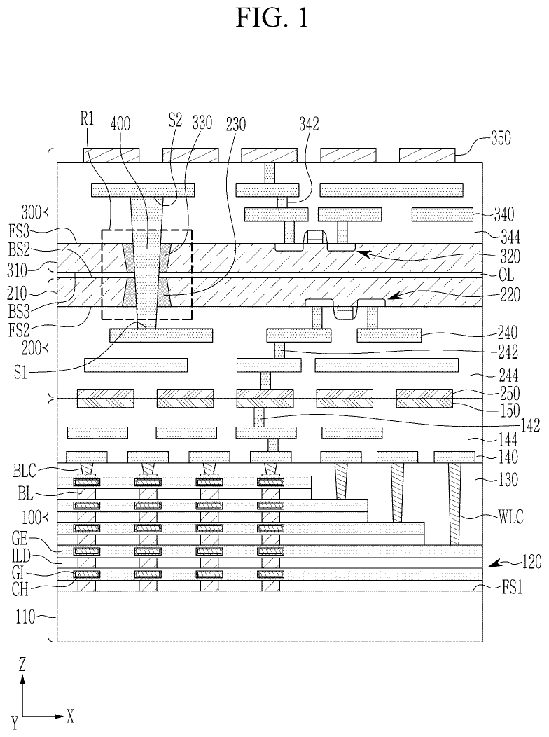

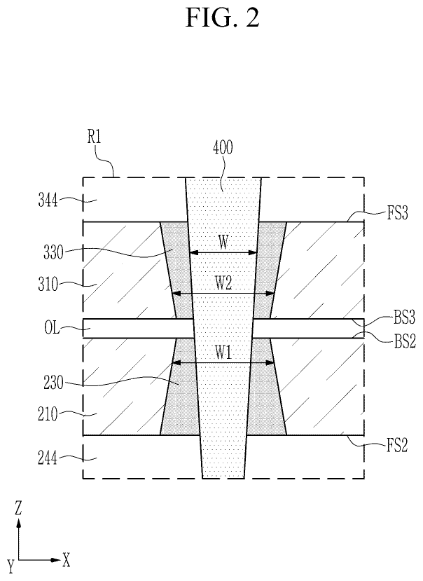

Hereinafter, a semiconductor device according to an embodiment will be described with reference to FIG. 1 and FIG. 2.

FIG. 1 illustrates a cross-sectional view of a semiconductor device according to an embodiment, and FIG. 2 illustrates an enlarged view of a region R1 in FIG. 1.

Referring to FIGS. 1 and 2, a semiconductor device according to an embodiment includes a stacked cell structure 100, a first logic structure 200, a second logic structure 300, and a through via 400 connecting the first logic structure 100 and the second logic structure 300. The first logic structure 200 may be positioned on the cell structure 100, and the second logic structure 300 may be positioned on the first logic structure 200. The through via 400 may be positioned inside or may extend within the first logic structure 200 and the second logic structure 300.

The cell structure 100 may include a first substrate 110 and a plurality of memory cells positioned on the first substrate 110. The memory cells may be arranged in a first direction X and a second direction Y parallel to a front surface FS1 of the first substrate 110. The second direction Y may be, e.g., a direction perpendicular to the first direction X. The memory cells may be stacked in a third direction Z perpendicular to the front surface FS1 of the first substrate 110. The memory cells may have a 3D array structure. The memory cells may be referred to as a memory cell array.

The cell structure 100 may include a gate stacked structure 120 in which a gate electrodes GE and an interlayer insulating layer ILD are alternately stacked in the third direction Z perpendicular to the front surface FS1 of the first substrate 110. The gate electrode GE and the interlayer insulating layer ILD may extend in a direction parallel to the front surface FS1 of the first substrate 110 (e.g., the first direction X). The gate electrode GE and the interlayer insulating layer ILD may extend in the first direction X and may be longer as they are closer to the first substrate 110.

The cell structure 100 may include a plurality of bit lines BL positioned outside the gate stacked structure 120 and spaced apart in the direction parallel to the front surface FS1 of the first substrate 110 (e.g., the first direction X). Each of the bit lines BL may extend in the third direction Z perpendicular to the front surface FS1 of the first substrate 110.

Each of the memory cells may be connected to the bit line BL and the gate electrode GE, and when a voltage is applied to the gate electrode GE and the bit line BL, data may be read or written to the memory cell. The gate electrode GE may be referred to as a word line.

Each of the memory cells may include a channel CH. Although not shown, each of the memory cells may further include a capacitor connected to each channel CH. The channel CH may extend in the second direction Y. A first end of the channel CH along the second direction Y may be connected to the bit line BL, and a second end along the second direction Y may be connected to the capacitor. The first end of the channel CH along the second direction Y may be in contact with the bit line BL, and the second end along the second direction Y may be in contact with the capacitor.

A gate insulating layer GI may be positioned between the channel CH and the gate electrode GE. The channel CH may be spaced apart from the gate electrode GE by the gate insulating layer GI. Referring to FIG. 1, the channel CH extends through the gate electrode GE in the second direction Y, and the gate insulating layer GI may have a shape surrounding the channel CH, but the present disclosure is not necessarily limited thereto. For example, the channel CH may extend in the second direction Y on a first surface of the gate electrode GE, and the gate insulating layer GI may be positioned between the first surface of the gate electrode GE and the channel CH. The term “surrounding” (or “covering” or “filling”) as may be used herein may not require completely surrounding (or covering or filling) the described elements or layers, but may, for example, refer to partially surrounding (or covering or filling) the described elements or layers, for example, with voids or other discontinuities throughout.

In the above-described embodiment, the semiconductor device is described as being a vertically stacked dynamic random access memory (VSDRAM) in which the memory cells are vertically stacked, but the present disclosure is not necessarily limited thereto. For example, the semiconductor device may be changed to various memory devices such as a DRAM including a vertical channel transistor (VCT) or a buried channel array transistor, and a vertical NAND flash memory.

The cell structure 100 may include a first wiring layer 140, a first via 142, and a first insulating layer 144 on the memory cells. The cell structure 100 may include a bit line contact BLC connecting the bit line BL and the first wiring layer 140, and a word line contact WLC connecting the gate electrode GE and the first wiring layer 140.

The cell structure 100 may include a gate stacked structure 120 and a cell insulating layer 130 covering the bit lines BL. The bit line contact BLC and the word line contact WLC may extend through the cell insulating layer 130 in the third direction Z perpendicular to the front surface FS1 of the first substrate 110. The bit line contact BLC and the word line contact WLC may each extend in the third direction Z. A first end of the bit line contact BLC along the third direction Z may be connected to a respective bit line BL, and a second end along the third direction Z may be connected to the first wiring layer 140. The first end of the bit line contact BLC along the third direction Z may be in contact with the respective bit line BL, and the second end along the third direction Z may be in contact with the first wiring layer 140. A first end of the word line contact WLC along the third direction Z may be connected to a respective gate electrode GE, and a second end along the third direction Z may be connected to the first wiring layer 140. The first end of the word line contact WLC along the third direction Z may be in contact with the respective gate electrode GE, and the second end along the third direction Z may be in contact with the first wiring layer 140. Side surfaces of the bit line contact BLC and word line contact WLC may be surrounded by the cell insulating layer 130.

The first wiring layer 140 may be positioned on the cell insulating layer 130. The first wiring layer 140 may include a plurality of wiring layers. The wiring layers may be spaced apart in the third direction Z perpendicular to the front surface FS1 of the first substrate 110 by the first insulating layer 144. The first via 142 may connect the wiring layers of the first wiring layer 140 to each other. The first via 142 may connect the wiring layers by extending through the first insulating layer 144 in the third direction Z. The first wiring layer 140 and the first via 142 may be surrounded by the first insulating layer 144.

The cell structure 100 may include a first bonding pad 150 positioned on the first wiring layer 140. The first bonding pad 150 may be connected to the first wiring layer 140 by the first via 142. The first bonding pad 150 may be surrounded by the first insulating layer 144. The first bonding pad 150 may include a plurality of bonding pads. The bonding pads may be separated by the first insulating layer 144. The first bonding pad 150 may be embedded in a first surface of the first insulating layer 144. The first surface of the first bonding pad 150 may be exposed to the outside of the cell structure 100. The first surface of the first bonding pad 150 may be coplanar with or positioned at a substantially same level as the first surface of the first insulating layer 144 in which the first bonding pad 150 is embedded. The term “level” may be used herein to refer to a distance from a reference element or surface, for example, the first substrate 110, the second substrate 210, or the third substrate 310 (or surface thereof).

Each of the bit line BL, the gate electrode GE, the bit line contact BLC, the word line contact WLC, the first wiring layer 140, the first via 142, and the first bonding pad 150 may contain a conductive material. For example, the conductive material may include a metal, doped polysilicon, a conductive metal nitride, a conductive metal oxide, etc., but the present disclosure is not necessarily limited thereto. The channel CH may include a semiconductor material. For example, the semiconductor material may include, but is not necessarily limited to, silicon. Each of the interlayer insulating layer ILD, the gate insulating layer GI, the cell insulating layer 130, and the first insulating layer 144 may include an insulating material. For example, the insulating material may include a silicon oxide, a silicon nitride, a silicon nitride, etc., but the present disclosure is not necessarily limited thereto.

The first logic structure 200 may include a second substrate 210 and a first logic circuit 220 positioned on the second substrate 210. The first logic circuit 220 may be positioned on a front surface FS2 of the second substrate 210. The first logic circuit 220, which is a circuit that performs logical operations, may be formed of a combination of circuit elements such as transistors. The first logic circuit 220 may include a circuit that controls a plurality of memory cells. For example, the first logic circuit 220 may include a row decoder that selects a row of the memory cell array based on an address signal, a column decoder that selects a column of the memory cell array based on the address signal, a sense amplifier that detects and amplifies data in a memory cell, a word line driver that activates the word line of the selected row, etc., but the present disclosure is not limited thereto.

The first logic structure 200 may include a second wiring layer 240, a second via 242, and a second insulating layer 244 on the first logic circuit 220. The second wiring layer 240 may include a plurality of wiring layers. The wiring layers may be spaced apart in the third direction Z perpendicular to the front surface FS2 of the second substrate 210 by the second insulating layer 244. The second via 242 may connect the wiring layers of the second wiring layer 240 to each other. The second via 242 may connect the wiring layers by extending through the second insulating layer 244 in the third direction Z. The second via 242 may include a contact that extends through the second insulating layer 244 in the third direction Z to connect circuit elements constituting the second wiring layer 240 and the first logic circuit 220. For example, the contact may be connected to at least one of a source region or a drain region of a circuit element. The second wiring layer 240 and the second via 242 may be surrounded by the second insulating layer 244.

The first logic structure 200 may include a second bonding pad 250 positioned on the second wiring layer 240. The second bonding pad 250 may be connected to the second wiring layer 240 by the second via 242. The second bonding pad 250 may be surrounded by the second insulating layer 244. The second bonding pad 250 may include a plurality of bonding pads. The bonding pads may be separated by the second insulating layer 244. The second bonding pad 250 may be embedded in a first surface of the second insulating layer 244. The first surface of the second bonding pad 250 may be exposed to the outside of the first logic structure 200. The first surface of the second bonding pad 250 may be coplanar with or positioned at a substantially same level as the first surface of the second insulating layer 244 in which the second bonding pad 250 is embedded.

Each of the second wiring layer 240, the second via 242, and the second bonding pad 250 may include a conductive material. For example, the conductive material may include, but is not necessarily limited to, a metal. The second insulating layer 244 may include an insulating material. For example, the insulating material may include, but is not necessarily limited to, a silicon oxide.

A first side of the first logic structure 200 may be bonded to a first surface of the cell structure 100. The first surface of the first logic structure 200 may be formed of the second bonding pad 250 and the second insulating layer 244 surrounding the second bonding pad 250. The first surface of the cell structure 100 may be formed of the first bonding pad 150 and the first insulating layer 144 surrounding the first bonding pad 150. The second bonding pad 250 may contact the first bonding pad 150, and the second insulation layer 244 may contact the first insulation layer 144. As the first bonding pad 150 and the second bonding pad 250 come into contact, the cell structure 100 and the first logic structure 200 may be electrically connected.

For example, the first bonding pad 150 and the second bonding pad 250 may each include copper. That is, a copper-copper metal bond may be formed between the first bonding pad 150 and the second bonding pad 250, and an insulator-insulator covalent bond may be formed between the first insulation layer 144 and the second insulation layer 244. This bonding method may be referred to as a hybrid copper bonding (HCB) method.

The first insulating pattern 230 may be positioned within the second substrate 210. The first insulating pattern 230 may extend through the second substrate 210. The first insulating pattern 230 may extend in the third direction Z perpendicular to the front surface FS2 and a back surface BS2 of the second substrate 210. The first insulating pattern 230 may include a first surface coplanar with or positioned at a substantially same level as the front surface FS2 of the second substrate 210 and a second surface coplanar with or positioned at a substantially same level as the back surface BS2 of the second substrate 210. The first and second surfaces of the first insulating pattern 230 may face each other. The first insulating pattern 230 may have a shape having a width that becomes narrower (i.e., is tapered) from the first surface to the second surface.

The second logic structure 300 may include a third substrate 310 and a second logic circuit 320 positioned on the third substrate 310. The second logic circuit 320 may be positioned on a front surface FS3 of the third substrate 310. The second logic circuit 320, which is a circuit that performs logical operations, may be formed of a combination of circuit elements such as transistors. The second logic circuit 320 may include a plurality of memory cells and/or a circuit that controls the first logic circuit 220. For example, the second logic circuit 320 may include an input/output circuit that manages data transmission between the semiconductor device and an external system, but the present disclosure is not limited thereto.

The second logic structure 300 may include a third wiring layer 340, a third via 342, and a third insulation layer 344. The third wiring layer 340 may include a plurality of wiring layers. The wiring layers may be spaced apart in the third direction Z perpendicular to the front surface FS3 of the third substrate 310 by the third insulating layer 344. The third via 342 may connect the wiring layers of the third wiring layer 340 to each other. The third via 342 may connect the wiring layers by extending through the third insulating layer 344 in the third direction Z. The third via 342 may include a contact that extends through the third insulating layer 344 in the third direction Z to connect circuit elements constituting the third wiring layer 340 and the second logic circuit 320. For example, the contact may be connected to at least one of a source region or a drain region of a circuit element. The third wiring layer 340 and the third via 342 may be surrounded by the third insulating layer 344.

The second logic structure 300 may include an input/output pad 350 positioned on the third wiring layer 340. The input/output pad 350 may be connected to the third wiring layer 340 by the third via 342. The input/output pad 350 may be positioned on the third insulating layer 344. The input/output pad 350 may include a plurality of input/output pads. The input/output pads 350 may positioned on the third insulating layer 344 and spaced apart from each other in parallel directions (e.g., the first direction X and the second direction Y) on the front surface FS3 of the third substrate 310.

Each of the third wiring layer 340, the third via 342, and the input/output pad 350 may include a conductive material. For example, the conductive material may include, but is not necessarily limited to, a metal. The third insulating layer 344 may include an insulating material. For example, the insulating material may include, but is not necessarily limited to, a silicon oxide.

Although not shown, the input/output pad 350 may connect the semiconductor device to an external device. As described above, the input/output pad 350 may include a conductive material (e.g., copper), electrically connecting the semiconductor device to the external device.

The second insulating pattern 330 may be positioned within the third substrate 310. The second insulating pattern 330 may extend through the third substrate 310. The second insulating pattern 330 may extend in the third direction Z perpendicular to the front surface FS3 and a back surface BS3 of the third substrate 310. The second insulating pattern 330 may include a first surface coplanar with or positioned at a substantially same level as the front surface FS3 of the third substrate 310 and a second surface coplanar with or positioned at a substantially same level as the back surface BS3 of the third substrate 310. The first and second surfaces of the second insulating pattern 330 may face each other. The second insulating pattern 330 may have a shape having a width that becomes narrower (i.e., is tapered) from the first surface to the second surface.

A first surface of the second logic structure 300 may be bonded to a first surface of the first logic structure 200. The first surface of the second logic structure 300 may be the back surface BS3 of the third substrate 310, and the first surface of the first logic structure 200 may be the back surface BS2 of the second substrate 210. The back surface BS2 of the second substrate 210 and the back surface BS3 of the third substrate 310 may face each other, and an insulating layer OL may be disposed between the back surface BS2 of the second substrate 210 and the back surface BS3 of the third substrate 310. The insulating layer OL may include an oxide layer disposed on the back surface BS2 of the second substrate 210, and an oxide layer disposed on the back surface BS3 of the third substrate 310. For example, the oxide layer may include, but is not limited to, a silicon oxide.

In an embodiment, the first insulating pattern 230 and the second insulating pattern 330 are formed in the third direction Z perpendicular to the back surface BS2 of the second substrate 210 and the back surface BS3 of the third substrate 310. The insulating layer OL may be disposed between the first insulating pattern 230 and the second insulating pattern 330. Each of the first insulating pattern 230 and the second insulating pattern 330 may have a tapered shape having a width that becomes narrower (e.g., continuously) as it approaches the insulating layer OL. A width W1 of the first insulating pattern 230 and a width W2 of the second insulating pattern 330 may decrease as a distance from the insulating layer OL decreases. That is, the first insulating pattern 230 may have a minimum width on a surface that is in contact with the insulating layer OL and a maximum width on a surface that is in contact with the second insulating layer 244. The second insulating pattern 330 may have a minimum width on a surface that is in contact with the insulating layer OL and a maximum width on a surface that is in contact with the third insulating layer 344.

In an embodiment, the first insulating pattern 230 and the second insulating pattern 330 may have a symmetrical structure with respect to the insulating layer OL (i.e., with respect to an axis of symmetry in a plane that extends along the a surface of the insulating layer OL). The width W1 of the first insulating pattern 230 and the width W2 of the second insulating pattern 330 may be the same on a surface spaced apart from the insulating layer OL by a same distance.

The through via 400 may extend through the first insulating pattern 230 and the second insulating pattern 330 in the third direction Z. The through via 400 may extend through the insulating layer OL disposed between the first insulating pattern 230 and the second insulating pattern 330 in the third direction Z. A single through via 400 may extend through the first insulating pattern 230, the insulating layer OL, and the second insulating pattern 330.

The through via 400 may connect the second wiring layer 240 and the third wiring layer 340. In FIG. 1, the through via 400 is shown as being connected to a wiring layer closest to the second substrate 210 among the second wiring layers 240 and connected to a wiring layer second adjacent to the third substrate 310 among the third wiring layers 340, but the present disclosure is not limited thereto. The through via 400 simply connects one of the wiring layers of the second wiring layer 240 and one of the wiring layers of the third wiring layer 340.

The through via 400 may include a first surface S1 that is in contact with the second wiring layer 240 and a second surface S2 that is in contact with the third wiring layer 340. In an embodiment, the through via 400 may have a shape having a width that becomes narrower (i.e., is tapered) from the second surface S2 to the first surface S1.

In an embodiment, a side surface of the through via 400 may have a single angle of inclination in a cross-sectional view. For example, a width of the through via 400 may continuously become narrower from the first surface S1 to the second surface S2. This may be due to a process of forming an opening extending through the first insulating pattern 230 and the second insulating pattern 330 in a single process and forming a single through via 400 that fills the opening. However, the inclination angle of the side surface of the through via 400 is not necessarily limited thereto. According to another embodiment, the width of the through via 400 becomes narrower from the first surface S1 to the second surface S2, but the decrease may vary. That is, the inclination angle of the side surface of the through via 400 has an angle where the width of the through via 400 narrows as it goes from the first surface S1 to the second surface S2, but does not remain constant and changes at various angles (i.e., varies non-uniformly between the first surface S1 to the second surface S2).

A width W of the through via 400 may be smaller than a width W1 of the first insulating pattern 230 at a same level as the first insulating pattern 230, and may be smaller than a width W2 of the second insulating pattern 330 at a same level as the second insulating pattern 330. The through via 400 may be surrounded by the first insulating pattern 230 and the second insulating pattern 330. The through via 400 may be spaced apart from the second substrate 210 by the first insulating pattern 230 and from the third substrate 310 by the second insulating pattern 330.

The first insulating pattern 230 and the second insulating pattern 330 may serve as a stopper in a wafer thinning process for each of the back surface BS2 of the second substrate 210 and the back surface BS3 of the third substrate 310 in a manufacturing process for the semiconductor device. The wafer thinning process may be completed when the first insulating pattern 230 or the second insulating pattern 330 is exposed. The term “exposed” may be used to describe relationships between elements and/or certain intermediate processes in fabricating a completed semiconductor device, but may not necessarily require exposure of the particular region, layer, structure or other element in the context of the completed device. The first insulating pattern 230 and the second insulating pattern 330 may each include an insulating material. The through via 400 may be insulated from the second substrate 210 and the third substrate 310 by the first insulating pattern 230 and the second insulating pattern 330.

According to an embodiment, the semiconductor device may include the first insulating pattern 230 aligned with or otherwise overlapping the second insulating pattern 330 in the third direction Z perpendicular to the back surface BS2 of the second substrate 210 and the back surface BS3 of the third substrate 310 (also referred to as vertical alignment or vertical overlap). Components or layers described with reference to “overlap” in a particular direction may be at least partially obstructed by one another when viewed along a line extending in the particular direction or in a plane perpendicular to the particular direction. The through via 400 extends through the second insulating pattern 330 to connect the second wiring layer 240 and the third wiring layer 340, to electrically connect a plurality of logic structures in a vertical direction so as to reduce a horizontal area occupied by the logic circuit, thereby reducing a size of the semiconductor device.

According to an embodiment, a process of forming a separate spacer to insulate the through via 400 from the second substrate 210 and the third substrate 310 may be omitted by forming the through via 400 that extends through the first and second insulating patterns 230 and 330, which serve as a stop layer in the wafer thinning process.

According to an embodiment, two logic structures may be electrically connected in one process by forming one through via 400 having a width that becomes narrower from a surface that is in contact with the third wiring layer 340 to a surface that is in contact with the second wiring layer 240.

According to the above-described embodiment, the first logic structure 200 may be closer to the cell structure 100 than the second logic structure 300. Accordingly, the first logic circuit 220 may include a circuit (hereinafter referred to as a core circuit) that controls the memory cells. In addition to the core circuit, the second logic circuit 320 may include a circuit that supports an operation of a semiconductor device, particularly communication between external systems, which may be referred to as a peripheral circuit. The second logic structure 300 may include an input/output pad 350. Accordingly, the peripheral circuit included in the second logic circuit 320 may include an input/output circuit connected to the input/output pad 350.

In an embodiment, the first logic circuit 220 may include at least one of an arithmetic circuit that performs an operation using data stored in the memory cells and a buffer that temporarily stores data used in the arithmetic circuit, and the second logic circuit 320 may include at least one of an arithmetic circuit and a buffer. The buffer may be used as a cache memory for an arithmetic circuit. For example, the arithmetic circuit may be a neural processing unit (NPU), but the present disclosure is not necessarily limited thereto.

For example, the first logic circuit 220 may include an arithmetic circuit and a buffer, or the second logic circuit 320 may include an arithmetic circuit and a buffer. As another example, the first logic circuit 220 may include an arithmetic circuit and the second logic circuit 320 includes a buffer, or the second logic circuit 320 includes an arithmetic circuit and the first logic circuit 220 may include a buffer.

In an embodiment, the first logic circuit 220 may include a core circuit, and the second logic circuit 320 may include a peripheral circuit, an arithmetic circuit, and a buffer used by the arithmetic circuit. In an embodiment, the first logic circuit 220 may include a core circuit, an arithmetic circuit, and a buffer used by the arithmetic circuit, and the second logic circuit 320 may include a peripheral circuit. In an embodiment, the first logic circuit 220 may include a core circuit and an arithmetic circuit, and the second logic circuit 320 may include a buffer used by the arithmetic circuit and a peripheral circuit. In an embodiment, the first logic circuit 220 may include a core circuit and a buffer used by an arithmetic circuit, and the second logic circuit 320 may include an arithmetic circuit and a peripheral circuit. However, the embodiments are not limited thereto, and the core circuit, the peripheral circuit, the arithmetic circuit, and the buffer used by the arithmetic circuit may be included in the first logic circuit 220 and the second logic circuit 320 in various combinations.

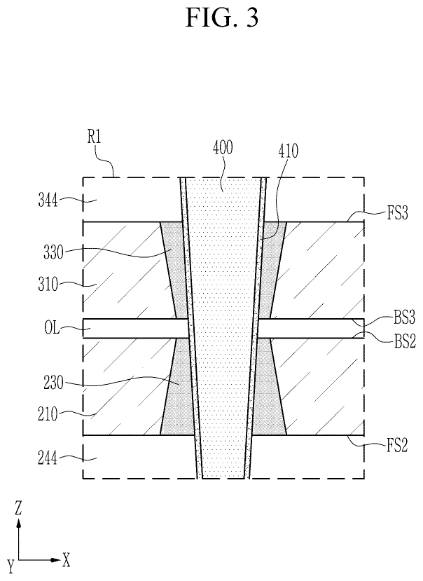

Hereinafter, a modified example of the semiconductor device of FIGS. 1 and 2 will be described with reference to FIG. 3.

FIG. 3 illustrates an enlarged view of the region R1 in FIG. 1 to describe a modified example of a semiconductor device according to an embodiment. Hereinafter, differences from the embodiments of FIGS. 1 and 2 will be mainly described, and redundant descriptions will be simplified or omitted.

Referring to FIG. 3, unlike in the embodiment of FIGS. 1 and 2, a spacer 410 may be positioned between the first insulating pattern 230 and the through via 400, and between the second insulating pattern 330 and the through via 400. The spacer 410 may be further positioned between the insulating layer OL and the through via 400. In FIG. 3, the spacer 410 is shown to be positioned further between the second insulating layer 244 and the through via 400, and between the third insulating layer 344 and the through via 400, but the present disclosure is necessarily limited thereto. For example, the spacer 410 may be positioned between the second insulating layer 244 and the through via 400, but may not be positioned between the third insulating layer 344 and the through via 400. That is, the spacer 410 may extend along less than (or up to) an entirety of the through via 400.

The spacer 410 may have a shape that conformally covers a side surface of the through via 400. The spacer 410 may have a cylindrical shape surrounding at least a portion of the side surface of the through via 400. The through via 400 extends in a third direction Z perpendicular to the back surface BS2 of the second substrate 210 and the back surface BS3 of the third substrate 310, so as to contact the second wiring layer 240 and the third wiring layer 340. The spacer 410 extends in the third direction Z along the side of the through via 400, but may not contact the second wiring layer 240 and/or the third wiring layer 340. For example, the second insulating layer 244 may be positioned between a first end of the spacer 410 and the second wiring layer 240 along the third direction Z, and the third insulating layer 344 may be positioned between a second end of the spacer 410 and the third wiring layer 340 along the third direction Z. As another example, the second end of the spacer 410 along the third direction Z may be in contact with the second wiring layer 240, and the third insulating layer 344 may be positioned between the second end of the spacer 410 and the third wiring layer 340 along the third direction Z. As another example, the second end of the spacer 410 along the third direction Z may be in contact with the third wiring layer 340, and the second insulating layer 244 may be positioned between the second end of the spacer 410 and the second wiring layer 240 along the third direction Z.

The spacer 410 may include an insulating material. The through via 400 may be insulated from the second substrate 210 and the third substrate 310 by the spacer 410.

According to the embodiment of FIG. 3, a spacer 410 may be further included between the through via 400 and the first insulating pattern 230 and between the through via 400 and the second insulating pattern 330, further preventing the through via 400 from being electrically connected to the second substrate 210 and the third substrate 310. For example, in an etching process for forming the through via 400, an interface between the first insulating pattern 230 and the second substrate 210 and/or an interface between the second insulating pattern 330 and the third substrate 310 may be etched. In this case, when the through via 400 is formed without forming the spacer 410, the through via 400 may not be insulated from the second substrate 210 and/or the third substrate 310. Accordingly, the semiconductor device may further include the spacer 410 to more reliably insulate the through via 400 from the second substrate 210 and the third substrate 310.

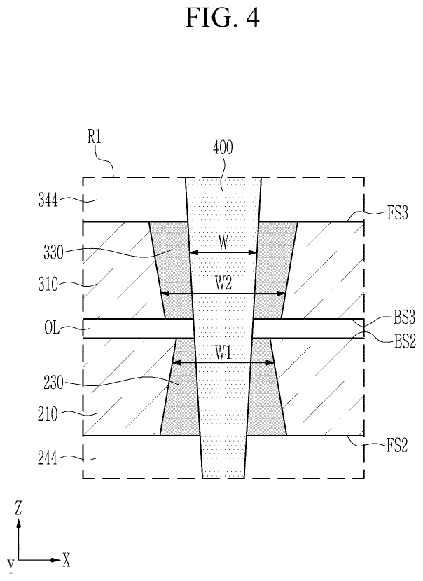

Hereinafter, a modified example of the semiconductor device of FIGS. 1 and 2 will be described with reference to FIG. 4.

FIG. 4 illustrates an enlarged view of the region R1 in FIG. 1 to describe a modified example of a semiconductor device according to an embodiment. Hereinafter, differences from the embodiments of FIGS. 1 and 2 will be mainly described, and redundant descriptions will be simplified or omitted.

Referring to FIG. 4, like in the embodiment of FIGS. 1 and 2, the width W1 of the first insulating pattern 230 and the width W2 of the second insulating pattern 330 may become narrower as they approach the insulating layer OL. The first insulating pattern 230 may have a maximum width at substantially a same level as the front surface FS2 of the second substrate 210 and a minimum width at substantially a same level as the back surface BS2 of the second substrate 210. The second insulating pattern 330 may have a maximum width at substantially a same level as the front surface FS3 of the third substrate 310 and a minimum width at substantially a same level as the back surface BS3 of the third substrate 310.

The width W of the through via 400 may be smaller than the width W1 of the first insulating pattern 230 at a same level as the first insulating pattern 230. In this case, the same level as the first insulating pattern 230 may indicate between a same level as an upper surface of the first insulating pattern 230 and a same level as a lower surface of the first insulating pattern 230. It may be smaller than the width W2 of the second insulation pattern 330 at a same level as the second insulation pattern 330. In this case, the same level as the second insulating pattern 330 may indicate between a same level as an upper surface of the second insulating pattern 330 and a same level as a lower surface of the second insulating pattern 330. The width W of the through via 400 may become narrower as it approaches the insulating layer OL inside the second insulating pattern 330. That is, within the second insulating pattern 330, the through via 400 may have a minimum width at substantially a same level as an interface between the second insulating pattern 330 and the insulating layer OL. The width W of the through via 400 may become narrower in a direction away from the insulating layer OL inside the first insulating pattern 230. That is, within the first insulating pattern 230, the through via 400 may have a maximum width at substantially a same level as an interface between the first insulating pattern 230 and the insulating layer OL. The maximum width of the through via 400 inside the first insulating pattern 230 may be smaller than the minimum width of the through via 400 inside the second insulating pattern 330.

Unlike in the embodiments of FIGS. 1 and 2, the first and second insulating patterns 230 and 330 may not have a symmetrical structure with respect to the insulating layer OL. The minimum width of the first insulating pattern 230 and the minimum width of the second insulating pattern 330 may be different from each other. The minimum width of the first insulating pattern 230 may be smaller than the minimum width of the second insulating pattern 330.

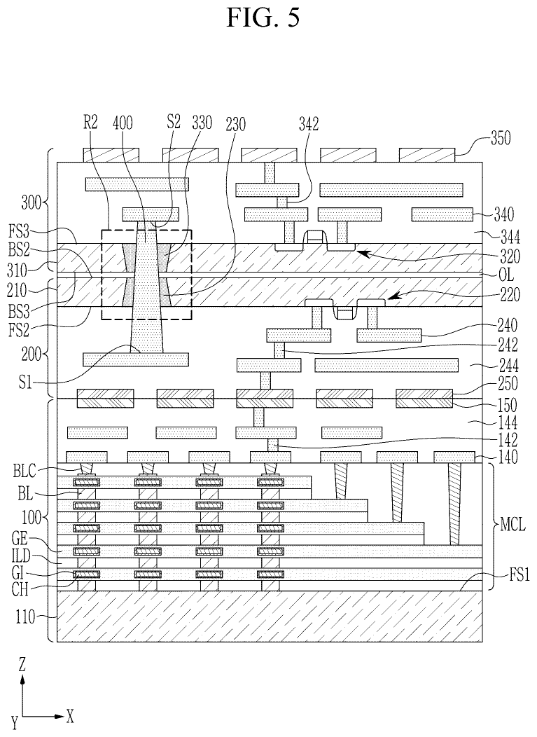

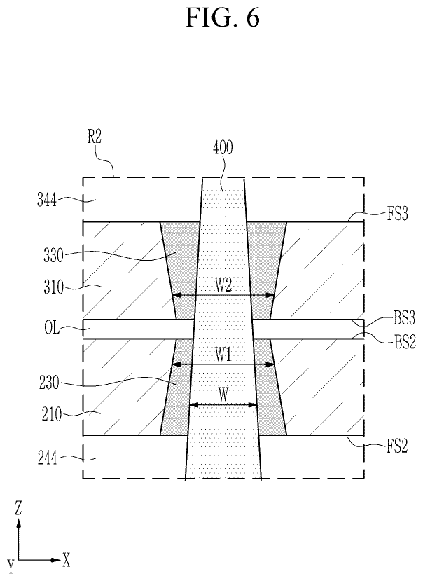

Hereinafter, a semiconductor device according to an embodiment will be described with reference to FIG. 5 and FIG. 6.

FIG. 5 illustrates a cross-sectional view of a semiconductor device according to an embodiment, and FIG. 6 illustrates an enlarged view of a region R2 in FIG. 5.

Hereinafter, differences from the embodiments of FIGS. 1 and 2 will be mainly described, and redundant descriptions will be simplified or omitted.

Referring to FIGS. 5 and 6, like in the embodiment of FIGS. 1 and 2, the first insulating pattern 230 and the second insulating pattern 330 are formed in the third direction Z perpendicular to the back surface BS2 of the second substrate 210 and the back surface BS3 of the third substrate 310. The insulating layer OL may be disposed between the first insulating pattern 230 and the second insulating pattern 330. The through via 400 may extend through the first insulating pattern 230, the insulating layer OL, and the second insulating pattern 330 in the third direction Z to connect the second wiring layer 240 and the third wiring layer 340.

The width W1 of the first insulating pattern 230 and the width W2 of the second insulating pattern 330 may become narrower as they approach the insulating layer OL. The first insulating pattern 230 and the second insulating pattern 330 may have a symmetrical structure with respect to the insulating layer OL. The width W1 of the first insulating pattern 230 and the width W2 of the second insulating pattern 330 may be the same on a surface spaced apart from the insulating layer OL by a same distance.

Unlike in the embodiment of FIGS. 1 and 2, the through via 400 may have a tapered shape having a width that becomes narrower (e.g., continuously) from the first surface S1 that is in contact with the second wiring layer 240 to the second surface S2 that is in contact with the third wiring layer 340.

In an embodiment, a side surface of the through via 400 may have a single angle of inclination in a cross-sectional view. For example, a width of the through via 400 may become narrower from the first surface S1 to the second surface S2. This may be due to a process of forming an opening extending through the first insulating pattern 230 and the second insulating pattern 330 in a single process and forming a single through via 400 that fills the opening. However, the inclination angle of the side surface of the through via 400 is not necessarily limited thereto. According to another embodiment, the width of the through via 400 becomes narrower from the first surface S1 to the second surface S2, but the decrease may vary. That is, the inclination angle of the side surface of the through via 400 has an angle where the width of the through via 400 narrows as it goes from the first surface S1 to the second surface S2, but does not remain constant and changes at various angles (i.e., varies non-uniformly).

The width W of the through via 400 may become narrower as it approaches the insulating layer OL inside the first insulating pattern 230. That is, within the first insulating pattern 230, the through via 400 may have a minimum width at substantially a same level as an interface between the first insulating pattern 230 and the insulating layer OL. The width W of the through via 400 may become narrower in a direction away from the insulating layer OL inside the second insulating pattern 330. That is, within the second insulating pattern 330, the through via 400 may have a maximum width at substantially a same level as an interface between the second insulating pattern 330 and the insulating layer OL. The maximum width of the through via 400 inside the second insulating pattern 330 may be smaller than the minimum width of the through via 400 inside the first insulating pattern 230.

According to an embodiment, the semiconductor device may include the first insulating pattern 230 aligned in the third direction Z perpendicular to the back surface BS2 of the second substrate 210 and the back surface BS3 of the third substrate 310, and the through via 400 extending through the second insulating pattern 330 to connect the second wiring layer 240 and the third wiring layer 340, to connect a plurality of logic structures in a vertical direction to reduce a horizontal area occupied by the logic circuit, thereby reducing a size of the semiconductor device. In this case, the first insulating pattern 230 and the second insulating pattern 330 may be components that serve as a stop layer in the wafer thin film forming process, and a process of forming a separate spacer to insulate the through via 400 from the second substrate 210 and the third substrate 310 may be omitted. In addition, the through via 400 may be formed in a single process, and may have a tapered shape having a width that becomes narrower (e.g., continuously) from a surface that is in contact with the second wiring layer 240 to a surface that is in contact with the third wiring layer 340. That is, two logic structures may be electrically connected in a single process.

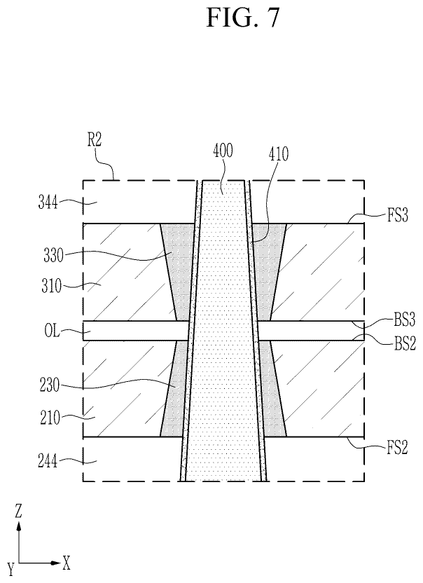

Hereinafter, a modified example of the semiconductor device of FIGS. 5 and 6 will be described with reference to FIG. 7.

FIG. 7 illustrates an enlarged view of the region R2 in FIG. 5 to describe a modified example of a semiconductor device according to an embodiment. Hereinafter, differences from the embodiments of FIGS. 5 and 6 will be mainly described, and redundant descriptions will be simplified or omitted.

Referring to FIG. 7, unlike in the embodiment of FIGS. 5 and 6, a spacer 410 may be positioned between the first insulating pattern 230 and the through via 400, and between the second insulating pattern 330 and the through via 400. The spacer 410 may be further positioned between the insulating layer OL and the through via 400. In FIG. 7, the spacer 410 is shown to be positioned further between the second insulating layer 244 and the through via 400, and between the third insulating layer 344 and the through via 400, but the present disclosure is necessarily limited thereto. For example, the spacer 410 may be positioned between the third insulating layer 344 and the through via 400, but may not be positioned between the second insulating layer 244 and the through via 400 (or vice versa).

The spacer 410 may have a shape that conformally covers a side surface of the through via 400. The spacer 410 may have a cylindrical shape surrounding at least a portion of the side surface of the through via 400. The through via 400 extends in a third direction Z perpendicular to the back surface BS2 of the second substrate 210 and the back surface BS3 of the third substrate 310, so as to contact the second wiring layer 240 and the third wiring layer 340. The spacer 410 extends in the third direction Z along the side of the through via 400, but may not contact the second wiring layer 240 and/or the third wiring layer 340. For example, the second insulating layer 244 may be positioned between a first end of the spacer 410 and the second wiring layer 240 along the third direction Z, and the third insulating layer 344 may be positioned between a second end of the spacer 410 and the third wiring layer 340 along the third direction Z. As another example, the second end of the spacer 410 along the third direction Z may be in contact with the second wiring layer 240, and the third insulating layer 344 may be positioned between the second end of the spacer 410 and the third wiring layer 340 along the third direction Z. As another example, the second end of the spacer 410 along the third direction Z may be in contact with the third wiring layer 340, and the second insulating layer 244 may be positioned between the second end of the spacer 410 and the second wiring layer 240 along the third direction Z.

The spacer 410 may include an insulating material. The through via 400 may be insulated from the second substrate 210 and the third substrate 310 by the spacer 410.

According to the embodiment of FIG. 7, the semiconductor device may further include a spacer 410 positioned between the first insulating pattern 230 and the through via 400, and between the second insulating pattern 330 and the through via 400, to more reliably insulate the through via 400 from the second substrate 210 and the third substrate 310.

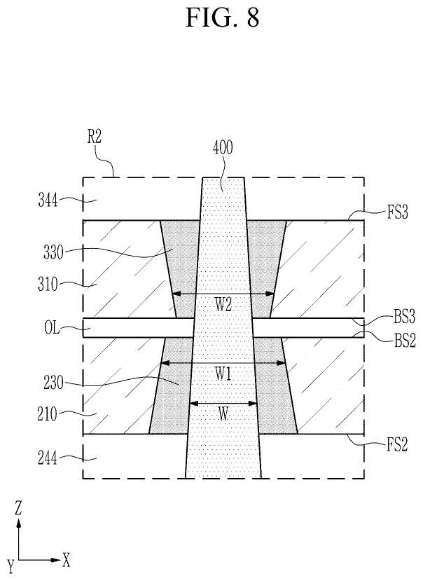

Hereinafter, a modified example of the semiconductor device of FIGS. 5 and 6 will be described with reference to FIG. 8.

FIG. 8 illustrates an enlarged view of the region R2 in FIG. 5 to describe a modified example of a semiconductor device according to an embodiment. Hereinafter, differences from the embodiments of FIGS. 5 and 6 will be mainly described, and redundant descriptions will be simplified or omitted.

Referring to FIG. 8, as in the embodiments of FIGS. 5 and 6, the width W of the through via 400 may be smaller than the width W1 of the first insulating pattern 230 at a same level as the first insulating pattern 230. The width W of the through via 400 may be smaller than the width W2 of the second insulating pattern 330 at a same level as the second insulating pattern 330. The width W1 of the first insulating pattern 230 and the width W2 of the second insulating pattern 330 may become narrower as they approach the insulating layer OL. The first insulating pattern 230 may have a maximum width at substantially a same level as the front surface FS2 of the second substrate 210 and a minimum width at substantially a same level as the back surface BS2 of the second substrate 210. The second insulating pattern 330 may have a maximum width at substantially a same level as the front surface FS3 of the third substrate 310 and a minimum width at substantially a same level as the back surface BS3 of the third substrate 310.

Unlike in the embodiments of FIGS. 5 and 6, the first and second insulating patterns 230 and 330 may not have a symmetrical structure with respect to the insulating layer OL. The minimum width of the first insulating pattern 230 and the minimum width of the second insulating pattern 330 may be different from each other. The minimum width of the second insulating pattern 330 may be smaller than the minimum width of the first insulating pattern 230.

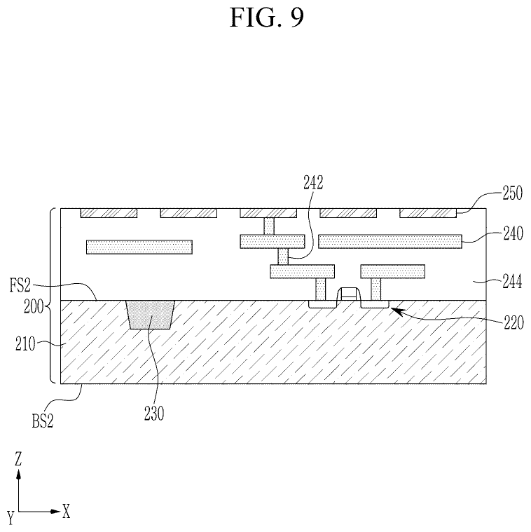

Hereinafter, a manufacturing method for the semiconductor device of FIGS. 1 and 2 will be described with reference to FIGS. 9 to 16.

FIG. 9 to FIG. 16 illustrate cross-sectional views showing intermediate fabrication process operations in a manufacturing method for a semiconductor device according to embodiments. According to operations of FIGS. 9 to 16, the semiconductor devices of FIGS. 1 and 2 may be manufactured.

Referring to FIG. 9, the first logic circuit 220 may be positioned on the front surface FS2 of the second substrate 210. The first logic circuit 220, which is a circuit that performs logical operations, may be formed of a combination of circuit elements such as transistors.

In an embodiment, the first logic circuit 220 may include a circuit that controls a plurality of memory cells. For example, the first logic circuit 220 may include a row decoder that selects a row of the memory cell array based on an address signal, a column decoder that selects a column of the memory cell array based on the address signal, a sense amplifier that detects and amplifies data in a memory cell, a word line driver that activates the word line of the selected row, etc., but the present disclosure is not limited thereto.

However, the embodiments of the present disclosure are not limited thereto. In an embodiment, the first logic circuit 220 may include at least one of an arithmetic circuit that performs an operation using data stored in the memory cells and a buffer that temporarily stores data used in the arithmetic circuit. For example, the arithmetic circuit may be an NPU, and the buffer may be a cache memory of the NPU, but the present disclosure is not limited thereto.

The first insulating pattern 230 may be formed inside the second substrate 210. For example, a recessed trench may be formed from the front surface FS2 to the back surface BS2 of the second substrate 210, and the first insulating pattern 230 may be formed by filling the trench with an insulating material.

The first insulating pattern 230 may have a shape having a width that becomes narrower from the front surface FS2 to the back surface BS2 of the second substrate 210. The first insulating pattern 230 may include a first surface coplanar with or positioned at a substantially same level as the front surface FS2 of the second substrate 210 and a second surface facing the first surface. The second surface may be positioned at a level between the front surface FS2 and the back surface BS2 of the second substrate 210.

The second wiring layer 240 may be positioned on the first logic circuit 220. For example, an insulating material layer may be formed to cover the second substrate 210, the first insulating pattern 230, and the first logic circuit 220, and the second via 242 may be formed to extend through the insulating material layer in the third direction Z perpendicular to the front surface FS2 of the second substrate 210. The second via 242 may include a contact that connects circuit elements constituting the second wiring layer 240 and the first logic circuit 220. A metal layer covering the insulating material layer and the contact may be formed, and the metal layer may be patterned to form the second wiring layer 240. The second wiring layer 240 including a plurality of wiring layers, the second via 242 connecting the wiring layers to each other in the third direction Z, and the second insulating layer 244 surrounding the second wiring layer 240 and the second via 242 may be formed by repeating the above-described process.

The second bonding pad 250 may be positioned on the second wiring layer 240. For example, an etching process may be performed on a first surface of the second insulating layer 244 to form a recess, and a metal layer may be formed to fill an inside of the recess and cover a first surface of the second insulating layer 244, and the second bonding pad 250 may be formed by performing a planarization process (e.g., a chemical mechanical polishing (CMP) process) on the metal layer.

The second bonding pad 250 may be embedded in a first surface of the second insulating layer 244. The second bonding pad 250 may be surrounded by the second insulating layer 244. The second bonding pad 250 may be connected to the second wiring layer 240 by the second via 242. The second bonding pad 250 may include a plurality of bonding pads spaced apart from each other in a parallel direction on the front surface FS2 of the second substrate 210. For example, a plurality of bonding pads may be arranged to be spaced apart in the first direction X, but the present disclosure is not limited thereto. Although not shown, a plurality of bonding pads may be further arranged to be spaced apart in the second direction Y.

For example, the second wiring layer 240, the second via 242, and the second bonding pad 250 may each include copper, but the present disclosure is not necessarily limited thereto, and it may be changed to various conductive materials.

The first logic structure 200 may be prepared by forming the first insulating pattern 230 inside the second substrate 210, and forming the first logic circuit 220, the second wiring layer 240, the second via 242, the second insulating layer 244, and the second bonding pad 250 on the second substrate 210.

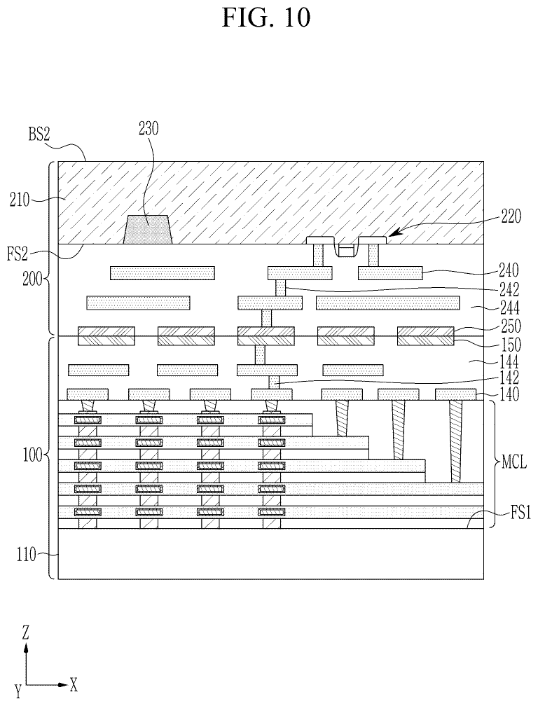

Referring to FIG. 10, the cell structure 100 may be prepared, and the first logic structure 200 may be adhered on the cell structure 100.

The cell structure 100 may be formed by stacking a memory cell layer MCL on the front surface FS1 of the first substrate 110. The memory cell layer MCL may include a plurality of memory cells, bit lines and word lines connected to the memory cells, and contacts connecting the bit lines and word lines to the first wiring layer 140 (e.g., the bit line contact BLC and the word line contact WLC in FIG. 1). The memory cells included in the memory cell layer MCL of FIG. 10 may be assumed to be the same as the memory cells in the embodiment of FIGS. 1 and 2. Accordingly, the contents described above with reference to FIGS. 1 and 2 may be equally applied to the memory cells.

The first wiring layer 140 may be disposed on the memory cell layer MCL. For example, a metal layer may be disposed on the memory cell layer MCL, and the metal layer may be patterned to form the first wiring layer 140. An insulating material layer covering the first wiring layer 140 may be formed, and the first via 142 connected to the first wiring layer 140 may be formed by penetrating the insulating material layer in the third direction Z perpendicular to the front surface FS1 of the first substrate 110. The first wiring layer 140 including a plurality of wiring layers, the first via 142 connecting the wiring layers to each other in the third direction Z, and the first insulating layer 144 surrounding the first wiring layer 140 and the first via 142 may be formed by repeating the above-described process.

The first bonding pad 150 may be positioned on the first wiring layer 140. For example, an etching process may be performed on a first surface of the first insulating layer 144 to form a recess, and a metal layer may be formed to fill an inside of the recess and cover a first surface of the first insulating layer 144, and the second bonding pad 150 may be formed by performing a planarization process (e.g., a CMP process) on the metal layer.

The first bonding pad 150 may be embedded in a first surface of the first insulating layer 144. The first bonding pad 150 may be surrounded by the first insulating layer 144. The first bonding pad 150 may be connected to the first wiring layer 140 by the first via 142. The first bonding pad 150 may include a plurality of bonding pads spaced apart from each other in a parallel direction on the front surface FS1 of the first substrate 110. For example, a plurality of bonding pads may be arranged to be spaced apart in the first direction X, but the present disclosure is not limited thereto. Although not shown, a plurality of bonding pads may be further arranged to be spaced apart in the second direction Y.

For example, the first wiring layer 140, the first via 142, and the first bonding pad 150 may each include copper, but the present disclosure is not necessarily limited thereto, and it may be changed to various conductive materials.

The cell structure 100 may be prepared by forming the memory cell layer MCL including a plurality of memory cells, the first wiring layer 140, the first via 142, the first insulating layer 144, and the first bonding pad 150 on the front surface FS1 of the first substrate 110.

A bonding process may be performed to bond the first logic structure 200 onto the cell structure 100. For example, a respective planarization process (e.g., a CMP process) may be performed on a surface of the cell structure 100 on which the first bonding pad 150 is positioned and on a surface on which the second bonding pad 250 of the first logic structure 200 is positioned, and then the first bonding pad 150 and the second bonding pad 250 may be aligned or may otherwise overlap in the third direction Z. Next, pressure may be applied to first bond the first insulating layer 144 surrounding the first bonding pad 150 and the second insulating layer 244 surrounding the second bonding pad 250. Next, heat treatment (annealing) may be performed to bond the first bonding pad 150 and the second bonding pad 250.

The first bonding pad 150 and the second bonding pad 250 may include a metal material, and the first insulation layer 144 and the second insulation layer 244 may include an insulating material. For example, the first bonding pad 150 and the second bonding pad 250 may include copper, and the first insulating layer 144 and the second insulating layer 244 may include a silicon oxide, but the present disclosure is not necessarily limited thereto.

During a heat treatment process, a metallic bond may be formed between the first bonding pad 150 and the second bonding pad 250, and a covalent bond may be formed between the first insulating layer 144 and the second insulating layer 244. The cell structure 100 and the first logic structure 200 may be bonded without bumps by bringing the first bonding pad 150 and the second bonding pad 250 into contact and bringing the first insulating layer 144 and the second insulating layer 244 into contact.

According to an embodiment, the first logic structure 200 may be subjected to subsequent processes while adhered to the cell structure 100, so that a process of adhering the first logic structure 200 to a carrier substrate and removing the carrier substrate can be omitted, which may simplify the manufacturing process for a semiconductor device.

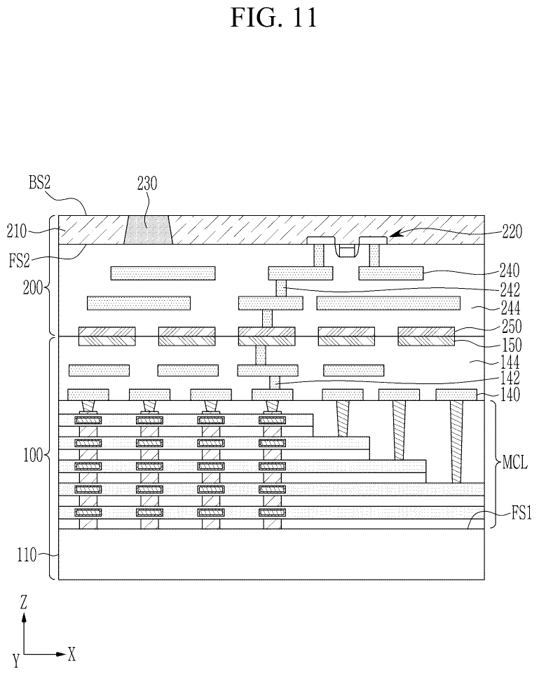

Referring to FIG. 11, a thickness of the second substrate 210 may be reduced by performing a wafer thinning process on a back surface of the second substrate 210. The wafer thinning process may be performed using the first insulating pattern 230 positioned inside the second substrate 210 as a stop layer. When the first insulating pattern 230 is exposed, the wafer thinning process may be completed.

Through the wafer thinning process, the back surface BS2 of the second substrate 210 may be coplanar with or positioned at a substantially same level as a surface of the first insulating pattern 230. The first surface of the first insulating pattern 230 may be coplanar with or positioned at a substantially same level as the front surface FS2 of the second substrate 210, and a second surface facing the first surface may be coplanar with or positioned at a substantially same level as the back surface BS2 of the second substrate 210. The first insulating pattern 230 may extend through the second substrate 210 in the third direction Z perpendicular to the front surface FS2 and the back surface BS2 of the second substrate 210.

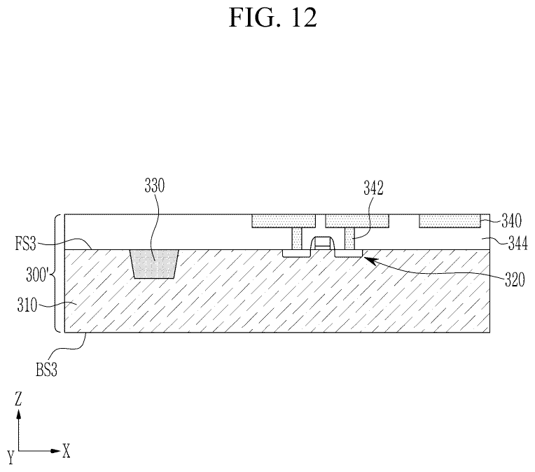

Referring to FIG. 12, the second logic circuit 320 may be positioned on the front surface FS3 of the third substrate 310. The second logic circuit 320, which is a circuit that performs logical operations, may be formed of a combination of circuit elements such as transistors.

In an embodiment, the second logic circuit 320 may include a plurality of memory cells and/or a circuit that controls the first logic circuit 220. For example, the second logic circuit 320 may include an input/output circuit that manages data transmission between the semiconductor device and an external system, but the present disclosure is not limited thereto.

However, the embodiments of the present disclosure are not limited thereto. In an embodiment, the second logic circuit 320 may include at least one of an arithmetic circuit that performs an operation using data stored in the memory cells and a buffer that temporarily stores data used in the arithmetic circuit. For example, the arithmetic circuit may be an NPU, and the buffer may be a cache memory of the NPU, but the present disclosure is not limited thereto.

In an embodiment, either the first logic circuit 220 or the second logic circuit 320 may further include an arithmetic circuit and a buffer. In an embodiment, one of the first logic circuit 220 or the second logic circuit 320 may further include an arithmetic circuit, and the other may further include a buffer.

The second insulating pattern 330 may be formed inside the third substrate 310. For example, a recessed trench may be formed from the front surface FS3 to the back surface BS3 of the third substrate 310, and the second insulating pattern 330 may be formed by filling the trench with an insulating material.

The second insulating pattern 330 may have a shape having a width that becomes narrower from the front surface FS3 to the back surface BS3 of the third substrate 310. The second insulating pattern 330 may include a first surface coplanar with or positioned at a substantially same level as the front surface FS3 of the third substrate 310 and a second surface facing the first surface. The second surface may be positioned at a level between the front surface FS3 and the back surface BS3 of the third substrate 310.

A portion of the third wiring layer 340 and a portion of the third via 342 may be disposed on the second logic circuit 320. For example, an insulating material layer may be formed to cover the third substrate 310, the second insulating pattern 330, and the second logic circuit 320, and the third via 342 may be formed to extend through the insulating material layer in the third direction Z perpendicular to the front surface FS3 of the third substrate 310. The third via 342 formed at this time may be a contact that connects circuit elements constituting the third wiring layer 340 and the second logic circuit 320. A metal layer covering the insulating material layer and the contact may be formed, and the metal layer may be patterned to form a layer closest to the front surface FS3 of the third substrate 310 among the wiring layers of the third wiring layer 340. Accordingly, a portion of the third wiring layer 340, a portion of the third via 342, and a portion of the third insulating layer 344 surrounding a portion of the third wiring layer 340 and a portion of the third via 342 may be formed.

In FIG. 12, it is shown that the second logic circuit 320 and a contact connecting the second logic circuit 320 and the third wiring layer 340 are formed on the front surface FS3 of the third substrate 310, and a portion of the third wiring layer 340 is formed before proceeding with the wafer thinning process for the back surface BS3 of the third substrate 310, but the embodiments are not limited thereto. For example, a contact connecting the second logic circuit 320 and the third wiring layer 340 may be positioned on the front surface FS3 of the third substrate 310, and after performing the wafer thin film process on the back surface BS3 of the third substrate 310, the third wiring layer 340 may be entirely formed.

The second logic circuit 320, a portion of the third via 342 (e.g., a contact connecting the second logic circuit 320 and the third wiring layer 340), a portion of the third wiring layer 340 (e.g., the layer closest to the front surface FS3 of the third substrate 310 among the wiring layers of the third wiring layer 340), and a portion of the third insulating layer 344 surrounding a portion of the third wiring layer 340 and a portion of the third via 342 may be positioned on the front surface (FS3) of the third substrate 310, which may be referred to as a preliminary structure 300′.

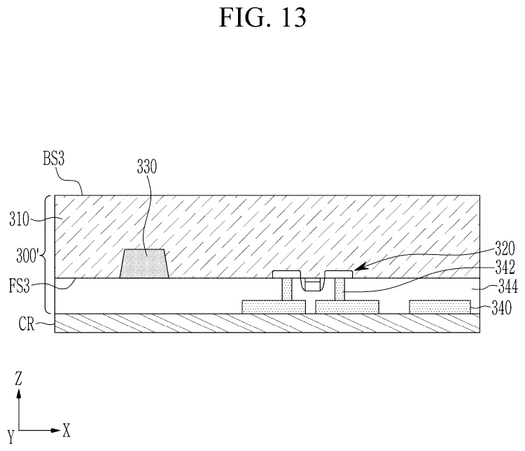

Referring to FIG. 13, the preliminary structure 300′ may be adhered to a carrier substrate CR such that the front surface FS3 of the third substrate 310 faces the carrier substrate CR. Accordingly, a process on the back surface BS3 of the third substrate 310 may be performed.

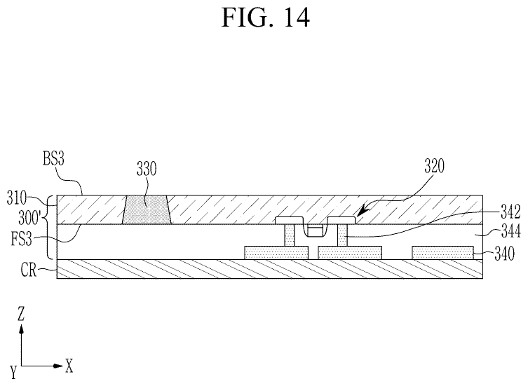

Referring to FIG. 14, a thickness of the third substrate 310 may be reduced by performing a wafer thinning process on a back surface of the third substrate 310. The wafer thinning process may be performed using the second insulating pattern 330 positioned inside the third substrate 310 as a stop layer. When the second insulating pattern 330 is exposed, the wafer thinning process may be completed.

Through the wafer thinning process, the back surface BS3 of the third substrate 310 may be coplanar with or positioned at a substantially same level as a surface of the second insulating pattern 330. The first surface of the second insulating pattern 330 may be coplanar with or positioned at a substantially same level as the front surface FS3 of the third substrate 310, and a second surface facing the first surface may be coplanar with or positioned at a substantially same level as the back surface BS3 of the third substrate 310. The second insulating pattern 330 may extend through the third substrate 310 in the third direction Z perpendicular to the front surface FS3 and the back surface BS3 of the third substrate 310.

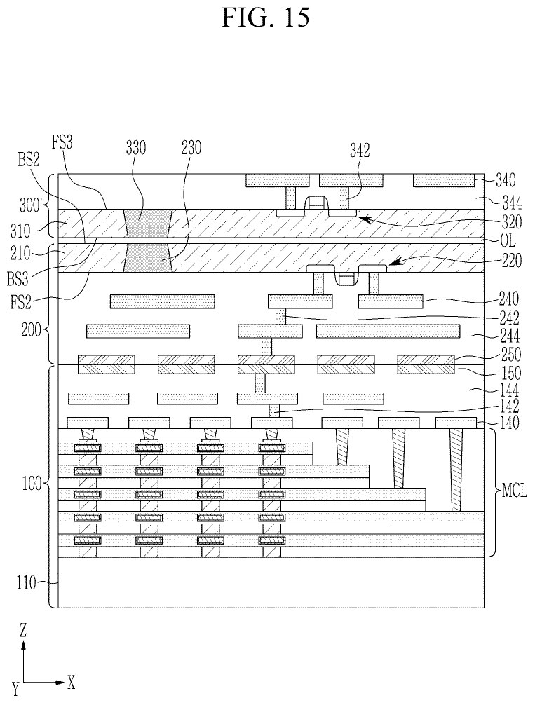

Referring to FIG. 15, the preliminary structure 300′ may be adhered onto the first logic structure 200. In this case, the first logic structure 200 may be attached to the cell structure 100.

For example, an oxide layer may be formed on each of the back surface BS3 of the third substrate 310 and the back surface BS2 of the second substrate 210. For example, an oxide layer may be formed through a thermal oxidation process or a chemical vapor deposition (CVD) process. For example, the oxide layer may include a silicon oxide. The oxide layer on the back surface BS3 of the third substrate 310 may cover the second insulating pattern 320. The oxide layer on the back surface BS2 of the second substrate 210 may cover the first insulating pattern 230. Next, the preliminary structure 300′ may be aligned on the first logic structure 200 such that the back surface BS3 of the third substrate 310 faces the rear surface BS2 of the second substrate 210, by turning the carrier substrate CR of FIG. 14 over. In this case, the first insulating pattern 230 and the second insulating pattern 330 are formed or oriented facing each other in the third direction Z perpendicular to the back surface BS2 of the second substrate 210 and the back surface BS3 of the third substrate 310. Next, the oxide layer on the back surface BS3 of the third substrate 310 and the oxide layer on the back surface BS2 of the second substrate 210 may be bonded using a high temperature and a high pressure. Accordingly, the insulating layer OL may be formed between the back surface BS3 of the third substrate 310 and the back surface BS2 of the second substrate 210, and between the second insulating pattern 330 and the first insulating pattern 230. The insulating layer OL may be formed of an oxide layer disposed on the back surface BS3 of the third substrate 310, and an oxide layer disposed on the back surface BS2 of the second substrate 210.

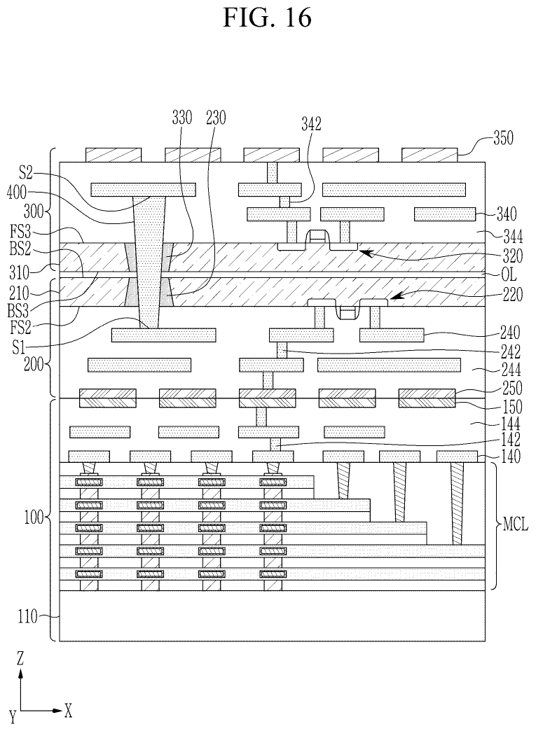

Referring to FIG. 16, the through via 400 may be formed to extend through the first insulating pattern 230 and the second insulating pattern 330 in the third direction Z perpendicular to the back surface BS2 of the second substrate 210 and the back surface BS3 of the third substrate 310. For example, a first trench extending through the third insulating layer 344, the second insulating pattern 330, the insulating layer OL, the first insulating pattern 230, and the second insulating layer 244 in the third direction Z may be formed by additionally depositing an insulating material layer on the preliminary structure 300′ of FIG. 15 and then performing an etching process. An etching process to form the first trench may be performed until a first surface of the second wiring layer 240 is exposed. That is, a first surface of the second wiring layer 240 may be a bottom surface of the first trench. A sidewall of the first trench may become narrower or tapered as it approaches the first surface of the second wiring layer 240. Next, a seed metal layer covering an inner wall and the bottom surface of the first trench may be deposited, and a plating process may be performed to fill an inside of the first trench with a metal material to form the through via 400. However, a method of forming the through via 400 is not limited thereto, and the through via 400 may be formed using various methods.

In addition, a second trench extending through the third insulating layer 344 in the third direction Z may be formed. An etching process to form the second trench may be performed until a first surface of the third wiring layer 340 is exposed. That is, a first surface of the third wiring layer 340 may be a bottom surface of the second trench. Next, a seed metal layer covering an inner wall and the bottom surface of the second trench may be deposited, and a plating process may be performed to fill an inside of the second trench with a metal material to form the third via 342.

In an embodiment, a process of forming the through via 400 and a process of forming the third via 342 may be performed sequentially, and an order thereof may be changed in various ways. However, the embodiments of the present disclosure are not limited thereto. For example, the first trench and the second trench may be formed at once in a single etching process.

Subsequently, a metal material layer covering the through via 400, the third via 342, and the third insulating layer 344 may be deposited and then patterned to further form the third wiring layer 340. For example, some of the wiring layers of the third wiring layer 340 may be formed in a process of FIG. 12, and the others may be formed in a process of FIG. 16.

Subsequently, an insulating material layer covering the third wiring layer 340 may be additionally deposited, and then the third via 342 extending through the insulating material layer in the third direction Z may be further formed. For example, the third via 342 may be formed to connect the third wiring layer 340 to the input/output pad 350, which will be described later.

Next, a metal layer covering the third insulating layer 344 and the third via 342 may be formed, and the input/output pad 350 may be formed by patterning the metal layer. In this case, a plurality of input/output pads may be formed. The input/output pads may be arranged on a first surface of the third insulating layer 344 and spaced apart in a direction parallel to the front surface FS3 of the third substrate 310. For example, the input/output pads may be arranged to be spaced apart in the first direction X, but the present disclosure is not limited thereto. Although not shown, the input/output pads may be arranged be spaced apart in the second direction Y. For example, the second direction Y may be a direction perpendicular to the first direction X.

For example, the third wiring layer 340, the third via 342, the through via 400, and the input/output pad 350 may each include copper, but the present disclosure is not necessarily limited thereto, and it may be changed to various metal materials.

The second logic structure 300 may be prepared by forming the second insulating pattern 330 inside the third substrate 310, and forming the second logic circuit 320, the third wiring layer 340, the third via 342, the third insulating layer 344, and the input/output pad 350 on the third substrate 310.

The through via 400 may extend through the third insulating layer 344, the second insulating pattern 330, the insulating layer OL, the first insulating pattern 230, and the second insulating layer 244 in the third direction Z to connect the third wiring layer 340 and the second wiring layer 240. The through via 400 may include a first surface S1 that is in contact with the second wiring layer 240 and a second surface S2 that is in contact with the third wiring layer 340. The through via 400 may have a shape having a width that becomes narrower or is tapered from the second surface S2 to the first surface S1. The through via 400 may be surrounded by the first insulating pattern 230 and the second insulating pattern 330. Accordingly, the through via 400 may be insulated from the second substrate 210 and the third substrate 310 by the first and second insulating patterns 230 and 330.

In FIG. 16, it is shown that the through via 400 is connected to a layer closest to the front surface FS2 of the second substrate 210 among the wiring layers of the second wiring layer 240, and is connected to a layer furthest from the front surface FS3 of the third substrate 310 among the wiring layers of the third wiring layer 340, but the present disclosure is not limited thereto. The through via 400 may be connected to any of the wiring layers of the second wiring layer 240 and any of the wiring layers of the third wiring layer 340.

According to an embodiment, the first logic structure 200 and the second logic structure 300 may be positioned in the vertical direction on the cell structure 100, and the through via 400 may be formed to connect the third wiring layer 340 of the second logic structure 300 and the second wiring layer 240 of the first logic structure 200, so a horizontal area occupied by a logic circuit in a semiconductor device may be reduced, thereby reducing a size of the semiconductor device. Additionally, a manufacturing process for the semiconductor device may be simplified by forming the through via 400 through a single etching process.

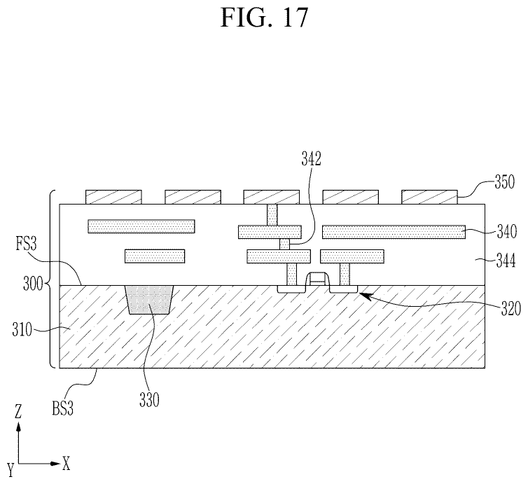

Hereinafter, a manufacturing method for the semiconductor device of FIGS. 5 and 6 will be described with reference to FIGS. 17 to 23.

FIG. 17 to FIG. 23 illustrate cross-sectional views showing intermediate fabrication process operations in a manufacturing method for a semiconductor device according to embodiments. According to operations of FIGS. 17 to 23, the semiconductor devices of FIGS. 5 and 6 may be manufactured.

Referring to FIG. 17, the second logic circuit 320 may be positioned on the front surface FS3 of the third substrate 310. The second logic circuit 320, which is a circuit that performs logical operations, may be formed of a combination of circuit elements such as transistors.

In an embodiment, the second logic circuit 320 may include a plurality of memory cells and/or a circuit that controls the first logic circuit 220. For example, the second logic circuit 320 may include an input/output circuit that manages data transmission between the semiconductor device and an external system, but the present disclosure is not limited thereto.

However, embodiments of the present disclosure are not limited thereto. In an embodiment, the second logic circuit 320 may include at least one of an arithmetic circuit that performs an operation using data stored in the memory cells and a buffer that temporarily stores data used in the arithmetic circuit. For example, the arithmetic circuit may be an NPU, and the buffer may be a cache memory of the NPU, but the present disclosure is not limited thereto.

The second insulating pattern 330 may be formed inside the third substrate 310. For example, a recessed trench may be formed from the front surface FS3 to the back surface BS3 of the third substrate 310, and the second insulating pattern 330 may be formed by filling the trench with an insulating material.

The second insulating pattern 330 may have a shape having a width that becomes narrower or tapered from the front surface FS3 to the back surface BS3 of the third substrate 310. The second insulating pattern 330 may include a first surface coplanar with or positioned at a substantially same level as the front surface FS3 of the third substrate 310 and a second surface facing the first surface. The second surface may be positioned at a level between the front surface FS3 and the back surface BS3 of the third substrate 310.

The third wiring layer 340 may be positioned on the second logic circuit 320. For example, an insulating material layer may be formed to cover the third substrate 310, the second insulating pattern 330, and the second logic circuit 320, and the third via 342 may be formed to extend through the insulating material layer in the third direction Z perpendicular to the front surface FS3 of the third substrate 310. The third via 342 may include a contact that connects circuit elements constituting the third wiring layer 340 and the second logic circuit 320. A metal layer covering the insulating material layer and the contact may be formed, and the metal layer may be patterned to form the third wiring layer 340. The third wiring layer 340 including a plurality of wiring layers, the third via 342 connecting the wiring layers to each other in the third direction Z, and the third insulating layer 344 surrounding the third wiring layer 340 and the third via 342 may be formed by repeating the above-described process.

The input/output pad 350 may be positioned on the third wiring layer 340. For example, a metal layer covering the third insulating layer 344 and the third via 342 may be formed, and the input/output pad 350 may be formed by patterning the metal layer. The input/output pad 350 may include a plurality of input/output pads. The input/output pads may be arranged on a first surface of the third insulating layer 344 and spaced apart in a direction parallel to the front surface FS3 of the third substrate 310. For example, the input/output pads may be arranged to be spaced apart in the first direction X, but the present disclosure is not limited thereto. Although not shown, the input/output pads may be arranged to be spaced apart in the second direction Y. For example, the second direction Y may be a direction perpendicular to the first direction X.

For example, the third wiring layer 340, the third via 342, and the input/output pad 350 may each include copper, but the present disclosure is not necessarily limited thereto, and it may be changed to various metal materials.

The second logic structure 300 may be prepared by forming the second insulating pattern 330 inside the third substrate 310, and forming the second logic circuit 320, the third wiring layer 340, the third via 342, the third insulating layer 344, and the input/output pad 350 on the third substrate 310.

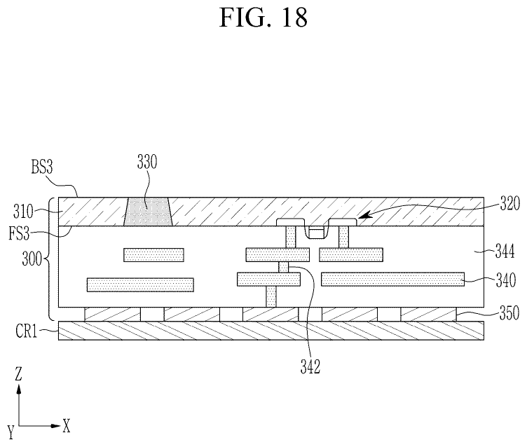

Referring to FIG. 18, the second logic structure 300 may be adhered to a first carrier substrate CR1 such that the front surface FS3 of the third substrate 310 faces the first carrier substrate CR1.

Next, a thickness of the third substrate 310 may be reduced by performing a wafer thinning process on a back surface of the third substrate 310. The wafer thinning process may be performed using the second insulating pattern 330 positioned inside the third substrate 310 as a stop layer. When the second insulating pattern 330 is exposed, the wafer thinning process may be completed.

Through the wafer thinning process, the back surface BS3 of the third substrate 310 may be coplanar with or positioned at a substantially same level as a surface of the second insulating pattern 330. The first surface of the second insulating pattern 330 may be coplanar with or positioned at a substantially same level as the front surface FS3 of the third substrate 310, and a second surface facing the first surface may be coplanar with or positioned at a substantially same level as the back surface BS3 of the third substrate 310. The second insulating pattern 330 may extend through the third substrate 310 in the third direction Z perpendicular to the front surface FS3 and the back surface BS3 of the third substrate 310.

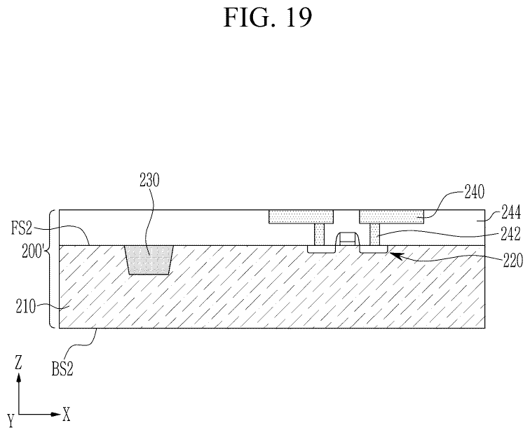

Referring to FIG. 19, the first logic circuit 220 may be positioned on the front surface FS2 of the second substrate 210. The first logic circuit 220, which is a circuit that performs logical operations, may be formed of a combination of circuit elements such as transistors. In an embodiment, the first logic circuit 220 may include a circuit that controls a plurality of memory cells. For example, the first logic circuit 220 may include a row decoder that selects a row of the memory cell array based on an address signal, a column decoder that selects a column of the memory cell array based on the address signal, a sense amplifier that detects and amplifies data in a memory cell, a word line driver that activates the word line of the selected row, etc., but the present disclosure is not limited thereto.

However, the embodiments of the present disclosure are not limited thereto. In an embodiment, the first logic circuit 220 may include at least one of an arithmetic circuit that performs an operation using data stored in the memory cells and a buffer that temporarily stores data used in the arithmetic circuit. For example, the arithmetic circuit may be an NPU, and the buffer may be a cache memory of the NPU, but the present disclosure is not limited thereto.

In an embodiment, either the first logic circuit 220 or the second logic circuit 320 may further include an arithmetic circuit and a buffer. In an embodiment, one of the first logic circuit 220 or the second logic circuit 320 may further include an arithmetic circuit, and the other may further include a buffer.

The first insulating pattern 230 may be formed inside the second substrate 210. For example, a recessed trench may be formed from the front surface FS2 to the back surface BS2 of the second substrate 210, and the first insulating pattern 230 may be formed by filling the trench with an insulating material.

The first insulating pattern 230 may have a shape having a width that becomes narrower or is tapered from the front surface FS2 to the back surface BS2 of the second substrate 210. The first insulating pattern 230 may include a first surface coplanar with or positioned at a substantially same level as the front surface FS2 of the second substrate 210 and a second surface facing the first surface. The second surface may be positioned at a level between the front surface FS2 and the back surface BS2 of the second substrate 210.

A portion of the second wiring layer 240 and a portion of the second via 242 may be disposed on the first logic circuit 220. For example, an insulating material layer may be formed to cover the second substrate 210, the first insulating pattern 230, and the first logic circuit 220, and the second via 242 may be formed to extend through the insulating material layer in the third direction Z perpendicular to the front surface FS2 of the second substrate 210. The second via 242 formed at this time may be a contact that connects circuit elements constituting the second wiring layer 240 and the first logic circuit 220. A metal layer covering the insulating material layer and the contact may be formed, and the metal layer may be patterned to form a layer closest to the front surface FS2 of the second substrate 210 among the wiring layers of the second wiring layer 240. Accordingly, a portion of the second wiring layer 240, a portion of the second via 242, and a portion of the second insulating layer 244 surrounding a portion of the second wiring layer 240 and a portion of the second via 242 may be formed.

In FIG. 19, it is shown that the first logic circuit 220 and a contact connecting the first logic circuit 220 and the second wiring layer 240 are formed on the front surface FS2 of the second substrate 210, and a portion of the second wiring layer 240 is formed before proceeding with the wafer thinning process for the back surface BS2 of the second substrate 210, but the embodiments are not limited thereto. For example, a contact connecting the first logic circuit 220 and the second wiring layer 240 may be positioned on the front surface FS2 of the second substrate 210, and after performing the wafer thin film process on the back surface BS2 of the second substrate 210, the second wiring layer 240 may be entirely formed.

The first logic circuit 220, a portion of the second via 242 (e.g., a contact connecting the first logic circuit 220 and the second wiring layer 240), a portion of the second wiring layer 240 (e.g., the layer closest to the front surface FS2 of the second substrate 210 among the wiring layers of the second wiring layer 240), and a portion of the second insulating layer 244 surrounding a portion of the second wiring layer 240 and a portion of the second via 242 may be positioned on the front surface FS2 of the second substrate 210, which may be referred to as a preliminary structure 200′.

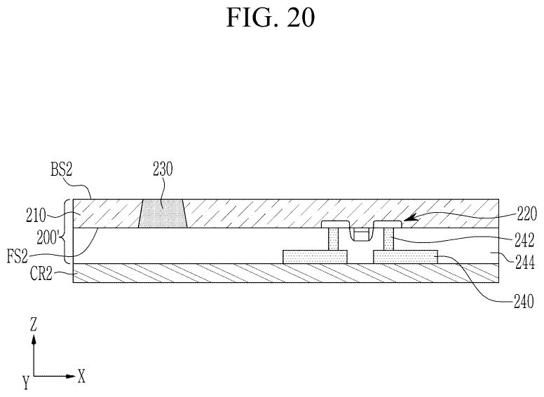

Referring to FIG. 20, the preliminary structure 200′ may be adhered to a second carrier substrate CR2 such that the front surface FS2 of the second substrate 210 faces the second carrier substrate CR2.

Next, a thickness of the second substrate 210 may be reduced by performing a wafer thinning process on a back surface of the second substrate 210. The wafer thinning process may be performed using the first insulating pattern 230 positioned inside the second substrate 210 as a stop layer. When the first insulating pattern 230 is exposed, the wafer thinning process may be completed.

Through the wafer thinning process, the back surface BS2 of the second substrate 210 may be coplanar with or positioned at a substantially same level as a surface of the first insulating pattern 230. The first surface of the first insulating pattern 230 may be coplanar with or positioned at a substantially same level as the front surface FS2 of the second substrate 210, and a second surface facing the first surface may be coplanar with or positioned at a substantially same level as the back surface BS2 of the second substrate 210. The first insulating pattern 230 may extend through the second substrate 210 in the third direction Z perpendicular to the front surface FS2 and the back surface BS2 of the second substrate 210.

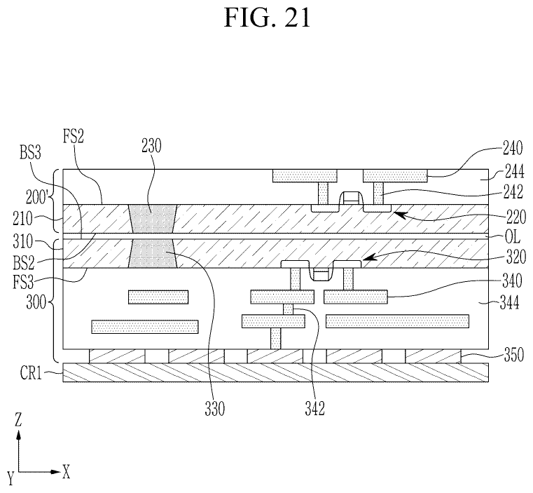

Referring to FIG. 21, the preliminary structure 200′ may be adhered onto the second logic structure 300. In this case, the second logic structure 300 may be attached to the first carrier substrate CR1.

For example, an oxide layer may be formed on each of the back surface BS3 of the third substrate 310 and the back surface BS2 of the second substrate 210. For example, an oxide layer may be formed through a thermal oxidation process or a chemical vapor deposition (CVD) process. For example, the oxide layer may include a silicon oxide. The oxide layer on the back surface BS3 of the third substrate 310 may cover the second insulating pattern 330. The oxide layer on the back surface BS2 of the second substrate 210 may cover the first insulating pattern 230. Next, the preliminary structure 200′ may be aligned on the first logic structure 300 such that the back surface BS2 of the second substrate 210 faces the back or rear surface BS3 of the third substrate 310, by turning the second carrier substrate CR2 of FIG. 20 over. In this case, the first insulating pattern 230 and the second insulating pattern 330 are formed in the third direction Z perpendicular to the back surface BS2 of the second substrate 210 and the back surface BS3 of the third substrate 310. Next, the oxide layer on the back surface BS3 of the third substrate 310 and the oxide layer on the back surface BS2 of the second substrate 210 may be bonded using a high temperature and a high pressure. Accordingly, the insulating layer OL may be formed between the back surface BS3 of the third substrate 310 and the back surface BS2 of the second substrate 210, and between the second insulating pattern 330 and the first insulating pattern 230. The insulating layer OL may be formed of an oxide layer disposed on the back surface BS3 of the third substrate 310, and an oxide layer disposed on the back surface BS2 of the second substrate 210.

After the preliminary structure 200′ is attached to the second logic structure 300, the second carrier substrate CR2 may be removed.

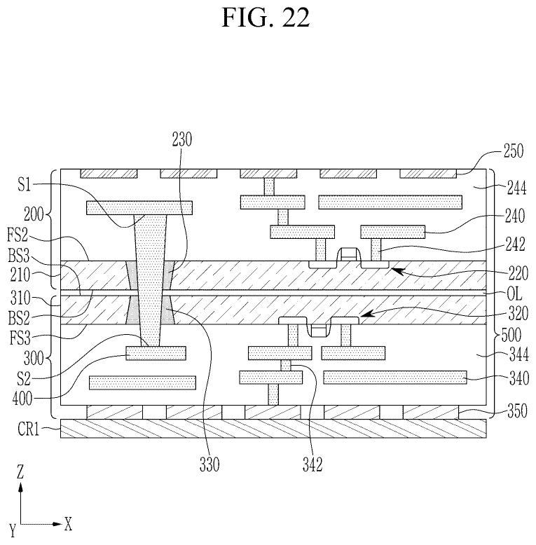

Referring to FIG. 22, the through via 400 may be formed to extend through the first insulating pattern 230 and the second insulating pattern 330 in the third direction Z perpendicular to the back surface BS2 of the second substrate 210 and the back surface BS3 of the third substrate 310. For example, a first trench extending through the second insulating layer 244, the first insulating pattern 230, the insulating layer OL, the second insulating pattern 330, and the third insulating layer 344 in the third direction Z may be formed by additionally depositing an insulating material layer on the preliminary structure 200′ of FIG. 21 and then performing an etching process. An etching process to form the first trench may be performed until a first surface of the third wiring layer 340 is exposed. That is, a first surface of the third wiring layer 340 may be a bottom surface of the first trench. A sidewall of the first trench may become narrower or may be tapered as it approaches the first surface of the third wiring layer 340. Next, a seed metal layer covering an inner wall and the bottom surface of the first trench may be deposited, and a plating process may be performed to fill an inside of the first trench with a metal material to form the through via 400.

In addition, a second trench extending through the second insulating layer 244 in the third direction Z may be formed. An etching process to form the second trench may be performed until a first surface of the second wiring layer 240 is exposed. That is, a first surface of the second wiring layer 240 may be a bottom surface of the second trench. Next, a seed metal layer covering an inner wall and the bottom surface of the second trench may be deposited, and a plating process may be performed to fill an inside of the second trench with a metal material to form the second via 242.

In an embodiment, a process of forming the through via 400 and a process of forming the second via 242 may be performed sequentially, and an order thereof may be changed in various ways. However, the embodiments of the present disclosure are not limited thereto. For example, the first trench and the second trench may be formed at once in a single etching process.

Subsequently, a metal material layer covering the through via 400, the second via 242, and the second insulating layer 244 may be deposited and then patterned to further form the second wiring layer 240. For example, some of the wiring layers of the second wiring layer 240 may be formed in a process of FIG. 19, and the others may be formed in a process of FIG. 22.

Subsequently, an insulating material layer covering the second wiring layer 240 may be additionally deposited, and then the second via 242 extending through the insulating material layer in the third direction Z may be further formed. For example, the second via 242 may be formed to connect the second wiring layer 240 to the second bonding pad 250, which will be described later.

Next, a metal layer covering the second insulating layer 244 and the second via 242 may be formed, and the second bonding pad 250 may be formed by patterning the metal layer. The second bonding pad 250 may include a plurality of bonding pads. The bonding pads may be arranged on a first surface of the second insulating layer 244 and spaced apart in a direction parallel to the front surface FS2 of the second substrate 210. For example, the bonding pads may be arranged to be spaced apart in the first direction X, but the present disclosure is not limited thereto. Although not shown, a plurality of bonding pads may be arranged to be spaced apart in the second direction Y. For example, the second direction Y may be a direction perpendicular to the first direction X.

For example, the second wiring layer 240, the second via 242, the through via 400, and the second bonding pad 250 may each include copper, but the present disclosure is not necessarily limited thereto, and it may be changed to various metal materials.

The first logic structure 200 may be prepared by forming the first insulating pattern 230 inside the second substrate 210, and forming the first logic circuit 220, the second wiring layer 240, the second via 242, the second insulating layer 244, and the second bonding pad 250 on the second substrate 210.

The through via 400 may extend through the second insulating layer 244, the first insulating pattern 230, the insulating layer OL, the second insulating pattern 330, and the third insulating layer 344 in the third direction Z to connect the second wiring layer 240 and the third wiring layer 340. The through via 400 may include a first surface S1 that is in contact with the second wiring layer 240 and a second surface S2 that is in contact with the third wiring layer 340. The through via 400 may have a shape having a width that becomes narrower or is tapered from the first surface S1 to the second surface S2. The through via 400 may be surrounded by the first insulating pattern 230 and the second insulating pattern 330. Accordingly, the through via 400 may be insulated from the second substrate 210 and the third substrate 310 by the first and second insulating patterns 230 and 330.

In FIG. 22, it is shown that the through via 400 is connected to a layer farthest from the front surface FS2 of the second substrate 210 among the wiring layers of the second wiring layer 240, and is connected to a layer closest to the front surface FS3 of the third substrate 310 among the wiring layers of the third wiring layer 340, but the present disclosure is not limited thereto. The through via 400 may be connected to any of the wiring layers of the second wiring layer 240 and any of the wiring layers of the third wiring layer 340.

According to an embodiment, the second logic structure 300 and the first logic structure 200 may be positioned in the vertical direction on the first carrier CR1, and the through via 400 may be formed to connect the second wiring layer 240 of the first logic structure 200 and the third wiring layer 340 of the second logic structure 300, so a horizontal area occupied by a logic circuit in a semiconductor device may be reduced, thereby reducing a size of the semiconductor device. Additionally, a manufacturing process for the semiconductor device may be simplified by forming the through via 400 through a single etching process.

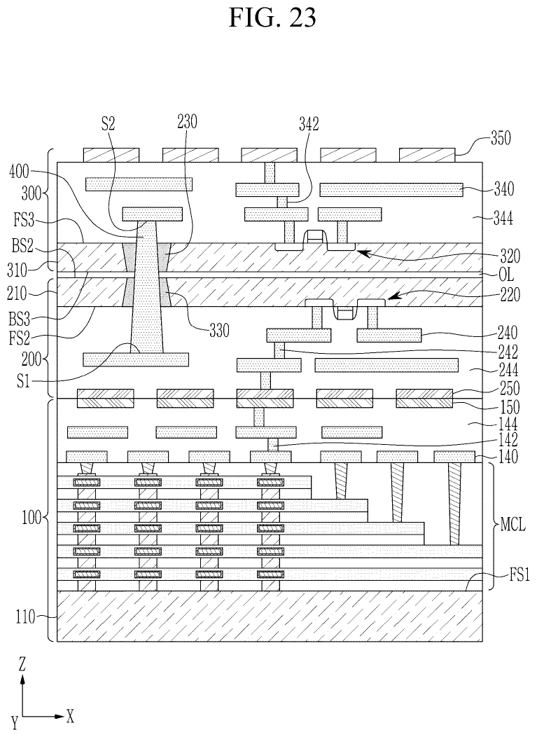

Referring to FIG. 23, the cell structure 100 may be prepared, and a stacked structure 500 in which the first logic structure 200 and the second logic structure 300 are stacked may be adhered onto the cell structure 100.

The cell structure 100 may form the memory cell layer MCL on the front surface FS1 of the first substrate 110. The memory cell layer MCL may include a plurality of memory cells, bit lines and word lines connected to the memory cells, and contacts connecting the bit lines and word lines to the first wiring layer 140 (e.g., the bit line contact BLC and the word line contact WLC in FIG. 1). The memory cells included in the memory cell layer MCL of FIG. 10 may be assumed to be the same as the memory cells in the embodiment of FIGS. 1 and 2. Accordingly, the contents described above with reference to FIGS. 1 and 2 may be similarly applied to the memory cells.

The first wiring layer 140 may be disposed on the memory cell layer MCL. For example, a metal layer may be disposed on the memory cell layer MCL, and the metal layer may be patterned to form the first wiring layer 140. An insulating material layer covering the first wiring layer 140 may be formed, and the first via 142 may be formed to connect the insulating material layer to the front surface FS1 of the first substrate 110 in the third direction Z. The first wiring layer 140 including a plurality of wiring layers, the first via 142 connecting the wiring layers to each other in the third direction Z, and the first insulating layer 144 surrounding the first wiring layer 140 and the first via 142 may be formed by repeating the above-described process.

The first bonding pad 150 may be positioned on the first wiring layer 140. For example, an etching process may be performed on a first surface of the first insulating layer 144 to form a recess, and a metal layer may be formed to fill an inside of the recess and cover a first surface of the first insulating layer 144, and the second bonding pad 150 may be formed by performing a planarization process (e.g., a CMP process) on the metal layer.

The first bonding pad 150 may be embedded in a first surface of the first insulating layer 144. The first bonding pad 150 may be surrounded by the first insulating layer 144. The first bonding pad 150 may be connected to the first wiring layer 140 by the first via 142. The first bonding pad 150 may include a plurality of bonding pads spaced apart from each other in a parallel direction on the front surface FS1 of the first substrate 110. For example, a plurality of bonding pads may be arranged to be spaced apart in the first direction X, but the present disclosure is not limited thereto. Although not shown, a plurality of bonding pads may be further arranged to be spaced apart in the second direction Y.

For example, the first wiring layer 140, the first via 142, and the first bonding pad 150 may each include copper, but the present disclosure is not necessarily limited thereto, and it may be changed to various metal materials.

The cell structure 100 may be prepared by forming the memory cell layer MCL including a plurality of memory cells, the first wiring layer 140, the first via 142, the first insulating layer 144, and the first bonding pad 150 on the front surface FS1 of the first substrate 110.

Next, the first carrier substrate CR1 of FIG. 22 may be turned over, and the stacked structure 500 may be adhered onto the cell structure 100 such that the first logic structure 200 faces the cell structure 200. For example, a planarization process (e.g., a CMP process) may be performed on a surface of the cell structure 100 on which the first bonding pad 150 is positioned and a surface on which the second bonding pad 250 of the first logic structure 200 is positioned, and then the first bonding pad 150 and the second bonding pad 250 may be aligned in the third direction Z by turning the first carrier substrate CR1 of FIG. 22 over. Next, pressure may be applied to first bond the first insulating layer 144 surrounding the first bonding pad 150 and the second insulating layer 244 surrounding the second bonding pad 250. Next, heat treatment (annealing) may be performed to bond the first bonding pad 150 and the second bonding pad 250.

The first bonding pad 150 and the second bonding pad 250 may include a metal material, and the first insulation layer 144 and the second insulation layer 244 may include an insulating material. For example, the first bonding pad 150 and the second bonding pad 250 may include copper, and the first insulating layer 144 and the second insulating layer 244 may include a silicon oxide, but the present disclosure is not necessarily limited thereto.

During a heat treatment process, a metallic bond may be formed between the first bonding pad 150 and the second bonding pad 250, and a covalent bond may be formed between the first insulating layer 144 and the second insulating layer 244. The cell structure 100 and the first logic structure 200 may be bonded without bumps by bringing the first bonding pad 150 and the second bonding pad 250 into contact and bringing the first insulating layer 144 and the second insulating layer 244 into contact.

After the stacked structure 500 is adhered onto the cell structure 100, the first carrier substrate CR1 may be removed.

According to an embodiment, the first logic structure 200 may be positioned on the cell structure 100, and the second logic structure 300 may be positioned on the first logic structure 200. The cell structure 100 and the first logic structure 200 may be electrically connected by the first bonding pad 150 and the second bonding pad 250, and the first logic structure 200 and the second logic structure 300 may be electrically connected by the through via 400. Accordingly, a horizontal area occupied by the logic circuit in the semiconductor device may be reduced, thereby reducing a size of the semiconductor device. Additionally, a manufacturing process for the semiconductor device may be simplified by forming the through via 400 through a single etching process.

While this disclosure has been described in connection with practical embodiments, it is to be understood that the disclosure is not limited to the disclosed embodiments, but, on the contrary, is intended to cover various modifications and equivalent dispositions included within the scope of the appended claims.

What is claimed is:

1. A semiconductor device comprising:
a cell structure comprising a first substrate and a plurality of memory cells on the first substrate;
a first logic structure on the cell structure opposite the first substrate, the first logic structure comprising a second substrate and a first logic circuit on the second substrate;
a second logic structure on the first logic structure opposite the cell structure, the second logic structure comprising a third substrate and a second logic circuit on the third substrate; and
a through via extending through a first insulating pattern in the second substrate and a second insulating pattern in the third substrate.

2. The semiconductor device of claim 1, wherein
the first logic structure further includes a first wiring layer electrically connected to the first logic circuit on the first substrate,
the second logic structure further includes a second wiring layer electrically connected to the second logic circuit on the second substrate, and
the through via continuously extends from the first wiring layer to the second wiring layer and provides electrical connection therebetween.

3. The semiconductor device of claim 2, wherein
a width of the through via is less than a width of the first insulating pattern within the first insulating pattern, and
the width of the through via is less than a width of the second insulating pattern within the second insulating pattern.

4. The semiconductor device of claim 3, wherein
the through via comprises a first surface that is in contact with the first wiring layer and a second surface that is in contact with the second wiring layer, and
the width of the through via is tapered from the second surface to the first surface.

5. The semiconductor device of claim 4, wherein
a minimum width of the first insulating pattern is less than a minimum width of the second insulating pattern.

6. The semiconductor device of claim 3, wherein
the through via comprises a first surface that is in contact with the first wiring layer and a second surface that is in contact with the second wiring layer, and
the width of the through via is tapered from the first surface to the second surface.

7. The semiconductor device of claim 6, wherein
a minimum width of the second insulating pattern is less than a minimum width of the first insulating pattern.

8. The semiconductor device of claim 1, wherein
the first logic circuit is on a front surface of the second substrate, and the second logic circuit is on a front surface of the third substrate, and
the first insulating pattern and the second insulating pattern overlap in a direction perpendicular to a back surface opposite the front surface of the second substrate and a back surface opposite the front surface of the third substrate.

9. The semiconductor device of claim 8, further comprising:
an insulating layer between the back surface of the second substrate and the back surface of the third substrate and between the first insulating pattern and the second insulating pattern,
wherein a width of each of the first and second insulating patterns is tapered toward the insulating layer.

10. The semiconductor device of claim 9, wherein
the first insulating pattern and the second insulating pattern have symmetrical structures with respect to the insulating layer.

11. The semiconductor device of claim 8, further comprising:
a spacer between the first insulating pattern and the through via, and between the second insulating pattern and the through via.

12. The semiconductor device of claim 1, wherein
the first logic circuit comprises a circuit that is configured to control the plurality of memory cells.

13. The semiconductor device of claim 1, wherein
the second logic structure further comprises an input/output pad configured to connect the semiconductor device to an external device,
the second logic circuit comprises an input/output circuit electrically connected to the input/output pad.

14. The semiconductor device of claim 1, wherein
the first logic circuit comprises at least one of an arithmetic circuit that is configured to perform an operation using data stored in the plurality of memory cells and a buffer that is configured to temporarily store data used in the arithmetic circuit, and
the second logic circuit comprises another of the arithmetic circuit and the buffer.

15. The semiconductor device of claim 1, wherein
the cell structure comprises a first bonding pad and a first insulating layer on the first bonding pad,
the first logic structure comprises a second bonding pad and a second insulating layer on the second bonding pad, and
the first bonding pad is in contact with the second bonding pad, and the first insulating layer is in contact with the second insulating layer.

16. A semiconductor device comprising:
a cell structure comprising a first substrate, a plurality of memory cells on the first substrate, and a first wiring layer electrically connected to the plurality of memory cells;
a first logic structure comprising a second substrate, a first logic circuit on the second substrate, and a second wiring layer electrically connected to the first logic circuit and the first wiring layer;
a second logic structure comprising a third substrate, a second logic circuit on the third substrate, and a third wiring layer electrically connected to the second logic circuit and the second wiring layer; and
a through via extending through the second substrate and the third substrate and electrically connecting the second wiring layer and the third wiring layer,
wherein the through via extends through a first insulating pattern in the second substrate and a second insulating pattern in the third substrate, and
wherein the through via is tapered from a first surface that is in contact with the second wiring layer to a second surface that is in contact with the third wiring layer, or is tapered from the second surface to the first surface.

17. The semiconductor device of claim 16, wherein
the first logic circuit is on a front surface of the second substrate, and the second logic circuit is on a front surface of the third substrate, and
the first insulating pattern and the second insulating pattern overlap in a direction perpendicular to a back surface that is opposite the front surface of the second substrate and a back surface that is opposite the front surface of the third substrate.

18. The semiconductor device of claim 17, further comprising:
an insulating layer between the back surface of the second substrate and the back surface of the third substrate, and between the first insulating pattern and the second insulating pattern,
wherein the first insulating pattern and the second insulating pattern have symmetrical structures with respect to the insulating layer.

19. A manufacturing method for a semiconductor package, the manufacturing method comprising:
forming a first logic circuit on a front surface of a first substrate, and a second logic circuit on a front surface of a second substrate;
reducing a thickness of the first substrate by performing a first wafer thinning process on a back surface that is opposite the front surface of the first substrate to expose a first insulating pattern in the first substrate;
reducing a thickness of the second substrate by performing a second wafer thinning process on a back surface that is opposite the front surface of the second substrate to expose a second insulating pattern in the second substrate;
forming a first oxide layer on the back surface of the first substrate and a second oxide layer on the back surface of the second substrate, and bonding the first oxide layer and the second oxide layer such that the first insulating pattern and the second insulating pattern overlap in a direction perpendicular to the back surfaces of the first and second substrates; and
forming a through via extending through the first insulating pattern and the second insulating pattern, wherein the first oxide layer and the second oxide layer are between the first insulating pattern and the second insulating pattern,
wherein a width of the through via is tapered from the front surface of the second substrate to the front surface of the first substrate, or from the front surface of the first substrate to the front surface of the second substrate.

20. The manufacturing method of claim 19, wherein the first wafer thinning process for the back surface of the first substrate is performed after:
providing a cell structure comprising a first bonding pad and a first insulating layer on the first bonding pad;
forming a first logic structure comprising a second bonding pad and a second insulating layer on the second bonding pad on the first logic circuit; and
adhering the first logic structure to the cell structure such that the first bonding pad and the second bonding pad are in contact and the first insulating layer and the second insulating layer are in contact.
